(19) United States
(12) Patent Application Publication
(10) Pub. No.: US 2025/0203838 A1
(43) Pub. Date: Jun. 19, 2025

(54) SEMICONDUCTOR CELL STRUCTURE

(71) Applicant: Invention and Collaboration Laboratory, Inc., Taipei City (TW)

(72) Inventors: Chao-Chun LU, Hsinchu (TW); Juang-Ying CHUEH, Hsinchu (TW); Wen-Hsien TU, Hsinchu (TW)

(73) Assignee: Invention and Collaboration Laboratory, Inc., Taipei City (TW)

(21) Appl. No.: 18/967,046

(22) Filed: Dec. 3, 2024

Related U.S. Application Data
(60) Provisional application No. 63/610,461, filed on Dec. 15, 2023.
(60) Provisional application No. 63/559,956, filed on Mar. 1, 2024.
(60) Provisional application No. 63/683,712, filed on Aug. 16, 2024.

(51) Int. Cl. H10B 10/00; G11C 11/412; H10D 89/10

(52) U.S. Cl. CPC H10B 10/12; G11C 11/412; H10D 89/10

(57) ABSTRACT

A semiconductor cell structure includes a semiconductor substrate with an original semiconductor surface having a first set active regions and a second set of active regions; a STI region surrounding the first set and the second set active regions, a set of PMOS transistors disposed in the first set active regions; a set of NMOS transistors disposed in the second set of active regions; a VDD contacting line electrically coupled to the set of PMOS transistors; a VSS contacting line electrically coupled to the set of NMOS transistors; wherein a bottom surface of each of the source regions and drain regions of the PMOS transistors and the NMOS transistors is isolated from the semiconductor substrate by a localized insulator region, and these localized insulator regions are disposed below the original semiconductor surface.

This application claims the benefit of U.S. provisional application Ser. No. 63/610,461 filed Dec. 15, 2023, Ser. No. 63/559,956 filed Mar. 1, 2024, and Ser. No. 63/683,712 filed Aug. 16, 2024; and the subject matter of which is incorporated herein by reference.

### BACKGROUND OF THE DISCLOSURE

### Field of the Disclosure

The present invention relates to semiconductor structure, and particularly to a SRAM cell or a logic standard cell structure with smaller device area and higher I-on/I-off Ratio.

### Description of the Related Art

Improvement in integrated circuit performance and cost has been achieved largely by process scaling technology according to Moore's Law, but the process variations in transistor performance with miniaturization down to the 28 nm (or lower) manufacture process is a challenge. Especially, semiconductor cell structures (such as static random-access memory (SRAM) cell structures or other devices) scaling for increased storage density, reduction in operating voltage (VDD) for lower stand-by power consumption, and enhanced yield necessary to realize larger-capacity SRAM devices become increasingly difficult to achieve.

A SRAM device is one of the commonly used memory. The SRAM device usually comprises SRAM cell array and peripheral circuits which includes row address decoder, column address decoder, and input/output circuits, etc. The SRAM cell array includes multiple SRAM cells, each SRAM cell incorporates a static latch with two cross-coupled inverters, so that it does not require DRAM periodic refreshing to retain the stored information, provided that there are adequate power supply voltages for the SRAM cells, i.e. a high level voltage VDD and a low level voltage VSS. The same high level voltage VDD and the low level voltage VSS are connected to the SRAM peripheral circuits (decoders, I/O circuits) as well. Furthermore, the high level voltage VDD usually corresponds to logic “1” stored in the SRAM cells and the low level voltage VSS corresponds to logic “0” stored in the SRAM cells.

FIG. 1 shows a SRAM cell structure, that is a six-transistor (6-T) SRAM cell. It consists of two cross-coupled inverters (PMOS pull-up transistors PU-1 and PU-2 and NMOS pull-down transistors PD-1 and PD-2) and two access transistors (NMOS pass-gate transistors PG-1 and PG-2). The high level voltage VDD is coupled to the PMOS pull-up transistors PU-1 and PU-2, and the low level voltage VSS are coupled to the NMOS pull-down transistors PD-1 and PD-2. When the word-line (WL) is enabled (i.e., a row is selected in an array), the access transistors are turned on, and connect the storage nodes (Node-1/Node-2) to the vertically-running bit-lines (BL and BL Bar).

FIG. 2 shows the “stick diagram” representing the layout and connection among the 6 transistors of the SRAM cell structure. The stick diagram usually just includes active regions (vertical red line) and gate lines (horizontal blue lines). Of course, there are still lots of contacts, on one hand directly coupled to the 6 transistors, and on the other hand, coupled to the word-line (WL), bit-lines (BL and BL Bar), high level voltage VDD, and low level voltage VSS, etc.

However, even miniaturization of the manufacture process down to the 28 nm or lower (so called, “minimum feature size”, “A”, or “F”), due to the interference among the size of the contacts, among layouts of the metal wires connecting the word-line (WL), bit-lines (BL and BL Bar), high level voltage VDD, and low level voltage VSS, etc., the total area of the SRAM cell represented by λ² or F² dramatically increases when the minimum feature size decreases, as shown in FIG. P3. Therefore, how to redesign the SRAM cell such that the total area of the SRAM cell represented by λ² could maintain within an acceptable range when the minimum feature size decreases is a challenge.

### SUMMARY OF THE DISCLOSURE

One object of the present disclosure is to provide a semiconductor cell structure, wherein the semiconductor cell structure includes a semiconductor substrate with an original semiconductor surface, a shallow trench isolation (STI) region, a set of PMOS transistors, a set of NMOS transistors, a VDD contacting line and a VSS contacting line. Wherein, the semiconductor substrate includes a first set active regions and a second set of active regions. The STI region surrounds the first set and the second set active regions. The set of PMOS transistors are disposed in the first set active regions, respectively; wherein each PMOS transistor includes a source region, a drain region, a gate structure, a PMOS region body and a channel region within the PMOS region body. The set of NMOS transistors are disposed in the second set of active regions, respectively; wherein each MMOS transistor includes a source region, a drain region, a gate structure, a NMOS region body and a channel region within the NMOS region body. The VDD contacting line is electrically coupled to the set of PMOS transistors. The VSS contacting line is electrically coupled to the set of NMOS transistors. Wherein a bottom surface of the source region of each PMOS transistor are isolated from the semiconductor substrate by a first plurality of localized insulator regions, a bottom surface of the drain region of each PMOS transistor are isolated from the semiconductor substrate by a second plurality of localized insulator regions, and the first and the second plurality of localized insulator regions are disposed below original semiconductor surface; a bottom surface of the source region of each NMOS transistor are isolated from the semiconductor substrate by a third plurality of localized insulator regions, a bottom surface of the drain region of each NMOS transistor are isolated from the semiconductor substrate by a fourth plurality of localized insulator regions, and the third and the fourth plurality of localized insulator regions are disposed below original semiconductor surface.

According to one embodiment of the present disclosure, either each PMOS region body or each NMOS region body is fully isolated from the semiconductor substrate by a localized isolation.

According to one embodiment of the present disclosure, a top surface of the STI region is higher than the original semiconductor surface, and the STI region surrounds the first, the second, the third and/or the fourth plurality of localized insulator regions.

According to one embodiment of the present disclosure, each localized insulator region of the first, the second, the third and/or the fourth plurality of localized insulator regions includes a L shape insulator within a concave under the original semiconductor surface.

According to one embodiment of the present disclosure, the source region of a first NMOS transistor is electrically contacting to the channel region of the first NMOS transistor, the source region of the first NMOS transistor is within the concave and includes a epitaxial LDD region laterally extending from the channel region of the first NMOS transistor and a epitaxial heavily doped region laterally extending from the epitaxial LDD region.

According to one embodiment of the present disclosure, a metal region is disposed within the STI region and the gate structure of the first NMOS transistor, and the metal region contacts a top surface and a most lateral sidewall of the source region of the first NMOS transistor.

According to one embodiment of the present disclosure, the VDD contacting line or the VSS contacting line is disposed under the original semiconductor surface.

According to one embodiment of the present disclosure, the VDD contacting line is electrically connected to a first PMOS transistor of the set of PMOS transistors through a contacting plug disposed in one of the first set active regions, and a sidewall of the contacting plug directly contacts to a sidewall of the VDD contacting line; or the VSS contacting line is electrically connected to a first NMOS transistor of the set of NMOS transistors through a contacting plug disposed in one of the second set active regions, and a sidewall of the contacting plug directly contacts to a sidewall of the VSS contacting line.

According to one embodiment of the present disclosure, the semiconductor cell structure further includes a thermal dissipation layer disposed within the STI region and under the original semiconductor surface, wherein a thermal conductivity of the thermal dissipation layer is higher than that of Si.

According to one embodiment of the present disclosure, the thermal dissipation layer surrounds the first set active regions and/or the second set active regions.

According to one embodiment of the present disclosure, the thermal dissipation layer extends from a position close to the first set active regions or the second set active regions to another position close to an edge of the semiconductor substrate.

According to one embodiment of the present disclosure, a first PMOS transistor of the set of PMOS transistors a first NMOS transistor of the set of NMOS transistors includes a convex semiconductor structure with at least a trench therein, the convex semiconductor structure includes a set of thin semiconductor bodies separate from each other, and there is no STI region between any two adjacent thin semiconductor bodies.

According to one embodiment of the present disclosure, a gate electrode distance between two of the set of NMOS transistors is determined by a width of an inserting dielectric layer.

According to one embodiment of the present disclosure, the semiconductor cell structure is a SRAM cell, and the SRAM cell further includes: a word line electrically coupled to the set of NMOS transistors; and a bit line and a complementary bit line electrically coupled to the set of NMOS transistors; wherein when a technology node λ is 16 nm, an cell area of the SRAM cell is between 105˜216λ²; or when the technology node λ is 10 nm, the cell area of the SRAM cell is between 166˜299λ²; or when the technology node λ is 7 nm, the cell area of the SRAM cell is between 271˜451λ²; or when the technology node λ is 5 nm, the cell area of the SRAM cell is between 432˜657λ²; or when the technology node λ is 3 nm, the cell area of the SRAM cell is between 1005˜1588λ².

Another object of the present disclosure is to provide a semiconductor cell structure, wherein the semiconductor cell structure includes a semiconductor substrate with an original semiconductor surface, a STI region, a set of transistors, a VDD contacting line and/or a VSS contacting line. Wherein, the semiconductor substrate includes a set of active regions. The STI region surrounds the set of active regions. The set of transistors are disposed in the set active regions; wherein each transistor includes a first epitaxial region, a second epitaxial region, and a gate structure between the first epitaxial region and the second epitaxial region. The VDD contacting line and the VSS contacting line are electrically coupled to the set of transistors. Wherein, the set of transistors includes a first transistor and a second transistor adjacent to each other, the first epitaxial region of the first transistor extends along a first direction; the first epitaxial region of the second transistor extends along the first direction; the first epitaxial region of the first transistor has a first edge surface, the first epitaxial region of the second transistor has a second edge surface facing the first edge surface; and first edge surface is parallel or substantially parallel to the second edge surface.

According to one embodiment of the present disclosure, both the first edge surface and the second edge surface are vertical or substantially vertical to the original semiconductor surface.

According to one embodiment of the present disclosure, a top surface of the STI region is higher than the original semiconductor surface, and surrounds three sides of the first epitaxial region of the first transistor and surrounds three sides of the first epitaxial region of the second transistor.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1 is a diagram illustrating a regular 6T SRAM according to the prior art;

FIG. 2 is a stick diagram corresponding to the 6T SRAM in FIG. 1, in which active regions are corresponding to the vertical lines and gate lines are corresponding to the horizontal lines;

FIG. 3 is a diagram illustrating the total area of the SRAM cell in terms of λ² (or F²) for different process dimension λ (or F) according to the currently available manufacture processes;

FIG. 4 is a cross-sectional view illustrating latch up distance between a traditional NMOS transistor and PMOS transistor in a traditional 6T SRAM cell;

FIG. 5(a) is a top view illustrating a miniaturized metal oxide semiconductor field effect transistor (mMOSFET) used in a SRAM cell structure according to one embodiment of the present disclosure;

FIGS. 5(b) to 5(g) are cross-sectional views illustrating a series of processing structures for forming the mMOSFET as depicted in FIG. 5(a);

FIG. 5(h) shows top view of the mMOSFET as depicted in FIG. 5(g);

FIG. 6(a) is a top view illustrating a combination of a PMOS transistor and a NMOS transistor used in a SRAM cell structure, according to one embodiment of the present disclosure;

FIG. 6(b) is a cross-sectional view illustrating the PMOS transistor taken along the cutline 1(X-axis) in FIG. 6(a);

FIG. 6(c) is a cross-sectional view illustrating the NMOS transistor taken along the cutline 2 (X-axis) in FIG. 6(a);

FIG. 6(d) is a cross-sectional view illustrating the PMOS transistor and the NMOS transistor taken along the cutline 3 (Y-axis) in FIG. 6(a);

FIG. 6(e) is a cross-sectional view illustrating a traditional CMOS structure which combines PMOS and NMOS structure;

FIG. 6(f) is a top view illustrating another combination structure of a PMOS and a NMOS used in a SRAM cell structure, according to another embodiment of the present disclosure;

FIG. 6(g) is a is a cross-sectional view illustrating the combination structure taken along the cutline (X-axis) in FIG. 6(f);

FIGS. 7(a) to 7(d) are cross-sectional views illustrating the processing structures for forming an NMOS transistor used in a SRAM cell structure, according to one embodiment of the present disclosure;

FIG. 7(e) is a perspective view of the NMOS transistor 700 as depicted in FIG. 7(d);

FIG. 8 is a perspective view of a FinFET used in a SRAM cell structure, according to one embodiment of the present disclosure;

FIG. 9A, (a) is a top view illustrating the temporary structure after the STI regions are formed; (b) is a cross-sectional view taken along Y-cut as shown in (a); and(c) is a cross-sectional view taken along X-cut shown as shown in FIG. 9A(a);

FIG. 9B, (a) is a top view illustrating the processing structure as SOD material and the photo-resistance layer 907 formed; (b) is a cross-sectional view taken along Y-cut as shown in (a); and(c) is a cross-sectional view taken along X-cut shown as shown in (a).

FIG. 9C, (a) is a top view illustrating the processing structure after the STI regions are formed; (b) is a cross-sectional view taken along Y-cut as shown in (a); and(c) is a cross-sectional view taken along X-cut as shown in (a);

FIG. 9D, (a) is a top view illustrating the processing structure after the SiOCN material is formed; (b) is a cross-sectional view taken along Y-cut as shown in (a); and(c) is a cross-sectional view taken along X-cut as shown in (a);

FIG. 9E, (a) is a top view of the processing structure after the SiN layer and the HDP oxide layer are formed; (b) is a cross section view taken along Y-cut as shown in (a); and(c) is a cross section view taken along X-cut shown in (a);

FIG. 9F is a 3D perspective view illustrating a CMOS which has a UGBL embedded and bounded by all insulators and connected to a drain region through a self-aligned vertical connector;

FIG. 10A, (a) is a top view illustrating the structure after the concave is formed; (b) is a cross-sectional view of the structure as depicted in (a) taken along the X direction; and(c) is a cross-sectional view of the structure as depicted in (a) taken along the Y direction;

FIG. 10B, (a) is a top view illustrating the structure after the nitride cap is formed; (b) is a cross-sectional view of the structure as depicted in (a) taken along the X direction; and(c) is a cross-sectional view of the structure as depicted in (a) taken along the Y direction;

FIG. 10C, (a) is a top view illustrating the structure after the STI region is etched down; (b) is a cross-sectional view of the structure as depicted in (a) taken along the X direction; and(c) is a cross-sectional view of the structure as depicted in F(a) taken along the Y direction;

FIG. 10D, (a) is a top view illustrating the structure after the conductive central pole is formed; (b) is a cross-sectional view of the structure as depicted in (a) taken along the X direction; and(c) is a cross-sectional view of the structure as depicted in (a) taken along the Y direction;

FIG. 10E, (a) is a top view illustrating the structure after the oxide spacer and a nitride spacer are formed; and (b) is a cross-sectional view of the structure as depicted in (a) taken along the X direction;

FIG. 10F, (a) is a top view illustrating the structure after the portions of the oxide layer are etched away to reveal the silicon sidewalls; and (b) is a cross-sectional view of the structure as depicted in (a) taken along the X direction;

FIG. 10G, (a) is a top view of illustrating a VTBFET used in a SRAM cell structure, according to one embodiment of the present disclosure; and (b) is a cross-sectional view of the VTBFET taken along the X direction as depicted in (a);

FIGS. 11A(1) to 11H are cross-sectional views illustrating the processing structures for forming a FinFET used in a SRAM cell structure, according to one embodiment of the present disclosure;

FIGS. 12A to 12F are a stick diagrams illustrating the processing lay-outs for forming a new 6T SRAM structure using the FinFET as depicted in FIG. 8;

FIGS. 13A to 13H are a stick diagrams illustrating the processing lay-outs for forming a new 6T SRAM structure applying the NMOS transistor as depicted in FIG. 7(e);

FIGS. 14A to 14D are cross-sectional views illustrating the processing structures for forming a new inverter cell structure applying the FinFETs and NMOS transistors provided by the aforementioned embodiments of the present disclosure; and

FIGS. 15A to 15E are cross-sectional views illustrating the processing structures for forming another new inverter cell structure, according to yet another embodiment of the present disclosure.

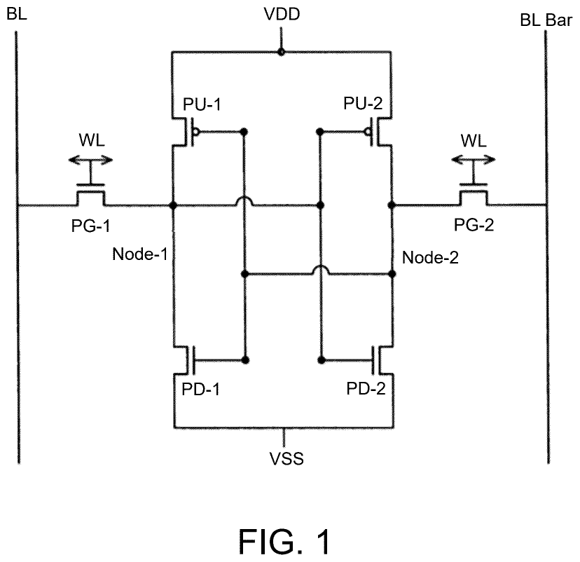

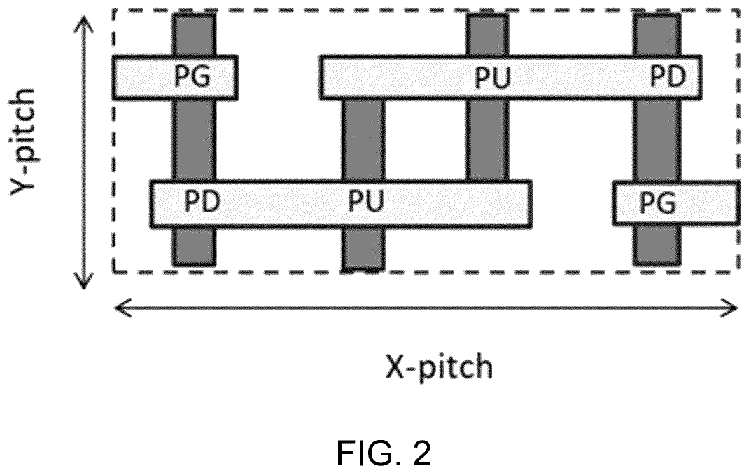

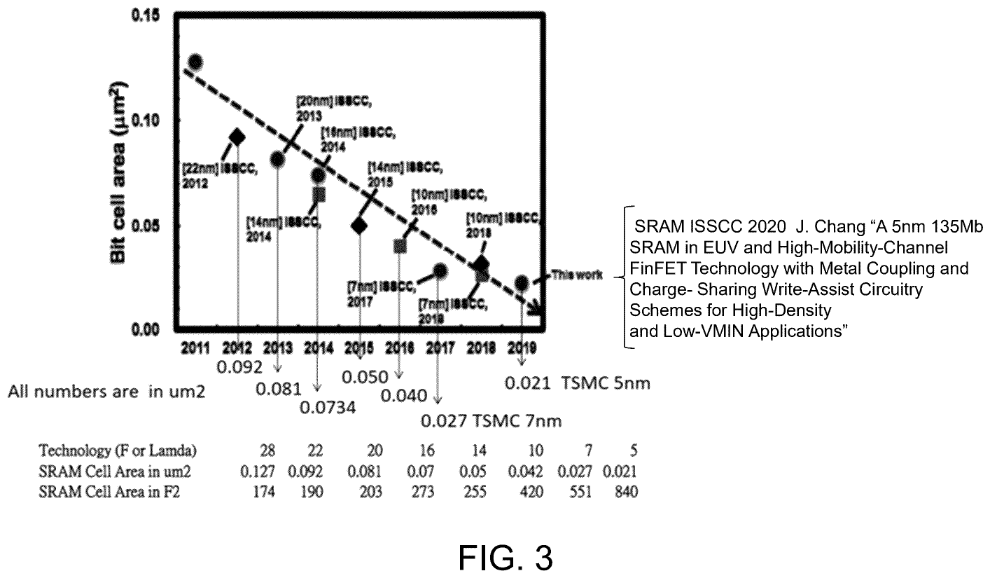

### DETAILED DESCRIPTION OF THE DISCLOSURE

The present disclosure provides a SRAM cell structure with smaller device area and higher I-on/I-off Ratio. The above and other aspects of the disclosure will become better understood by the following detailed description of the preferred but non-limiting embodiment(s). The following description is made with reference to the accompanying drawings:

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

This invention discloses a new SRAM cell structure includes a set of PMOS transistors and a set of NMOS transistors disposed in a bulk semiconductor substrate (such as, a SRAM cell structure with six-transistor CMOS formed in a bulk wafer substrate), the PMOS/NMOS transistors have selectively localized underground insulator layers (e.g. oxide layers) to isolate the diffusion regions (including source and drain regions) and/or body region (that is, the semiconductor body under the channel of the transistor) of the PMOS/NMOS transistors. Moreover, in one embodiment, the body region of the PMOS transistor is isolated from the bulk substrate by a localized isolation region, but the body region of the NMOS transistor is not isolated from the bulk substrate (or vice versa). Following embodiments disclosed here are several designs of the NMOS/PMOS transistors used to form the SRAM cell structure, which can reduce the cell area of the SRAM cell structure and thus enhance the performance as well as reduce the power in significant measurements, for the stand-alone SRAM devices and the embedded SRAM devices applied in Logic or System On Chip (SOC) designs.

### Embodiment 1 (NuCMOS Transistors-Minimal Dimension and Raised STI Regions)

This embodiment discloses a miniaturized metal oxide semiconductor field effect transistor (mMOSFET) 500 used in a SRAM cell structure, especially used in a 6T SRAM cell structure, wherein the device size can be precisely controlled by a stacked isolation region formed by self-alignment technology; meanwhile with the help of the localized isolations under the source/drain regions of the transistors, the distance from n+ region of the NMOS transistor to the p+ region of the PMOS transistor between the two adjacent transistor devices can be reduced but still can avoid latch-up issue without enlarge the size of the SRAM cell structure.

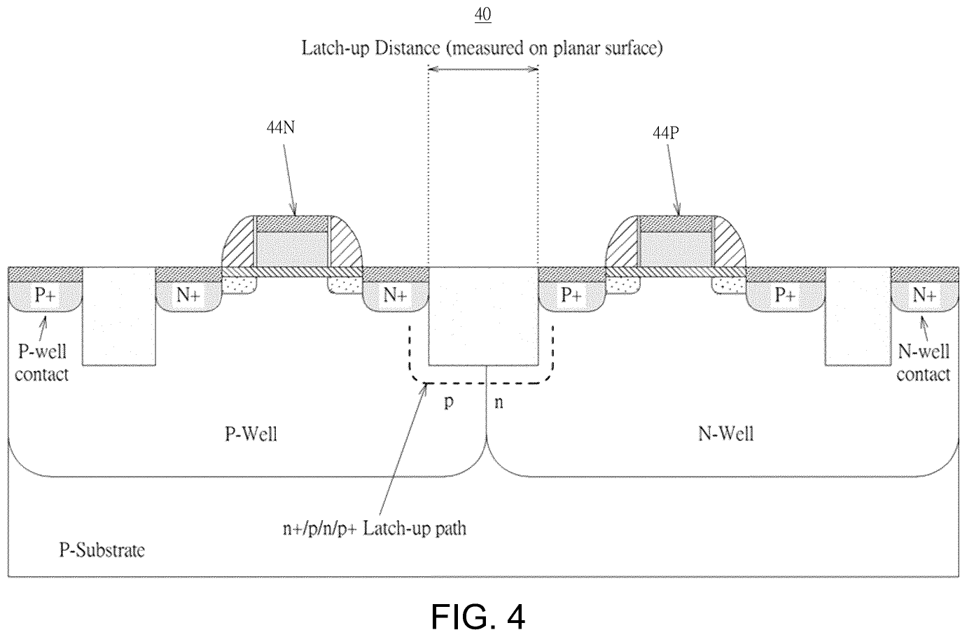

FIG. 4 is a cross-sectional view illustrating a traditional NMOS transistor 44N and PMOS transistor 44P in a traditional 6T SRAM cell structure 40. In the traditional 6T SRAM cell structure 40, at least there are one NMOS transistor 44N and one PMOS transistor 44P located respectively inside some adjacent regions of p-substrate 401 and n-well which have been formed next to each other within a close neighborhood, a parasitic junction structure called n+/p/n/p+ parasitic bipolar device is formed with its contour starting from the n+ region of the NMOS transistor to the p-well to the neighboring n-well and further up to the p+ region of the PMOS transistor 44P, as shown in FIG. 4. There are significant noises occurred on either n+/p junctions or p+/n junctions, an extraordinarily large current may flow through this n+/p/n/p+ junction abnormally which can possibly shut down some operations of CMOS circuits and to cause malfunction of the entire chip. Such an abnormal phenomenon called latch-up is detrimental for CMOS operations and must be avoided. One way to increase the immunity to latch-up which is certainly a weakness for CMOS is to increase the distance from n+ region to the p+ region. Thus, the increase of the distance from n+ region to the p+ region to avoid latch-up issue will also enlarge the size of the SRAM cell structure 40.

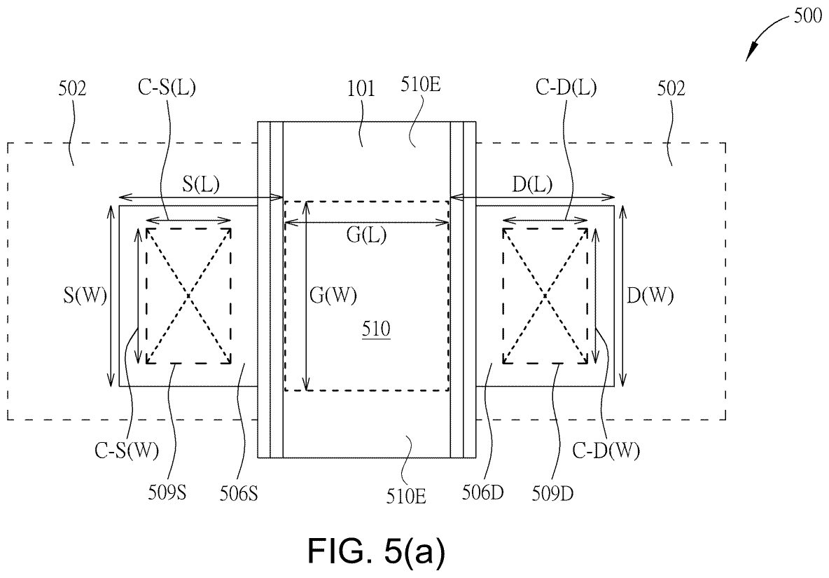

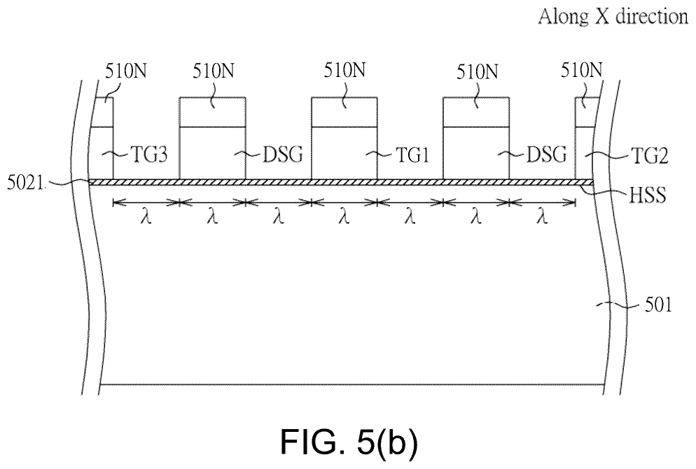

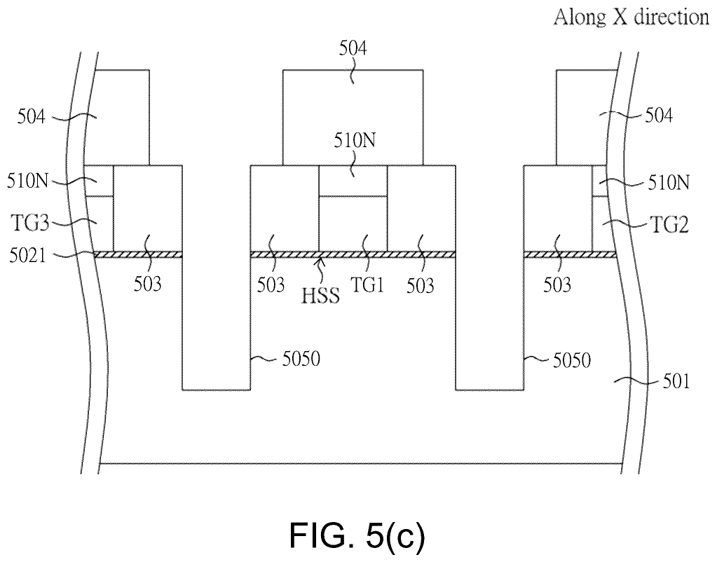

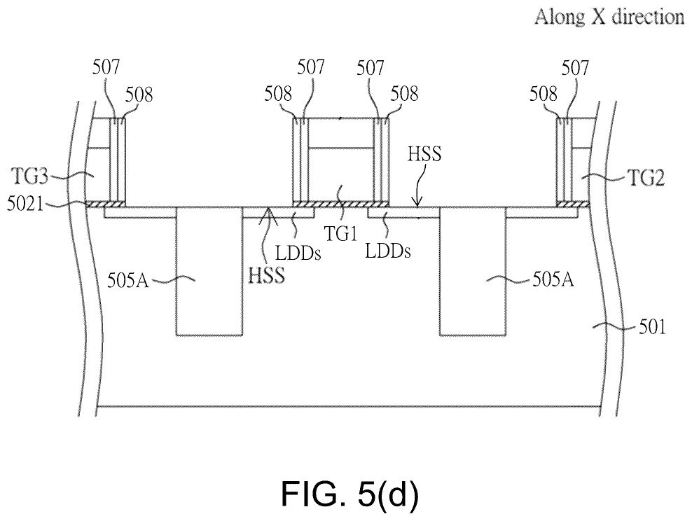

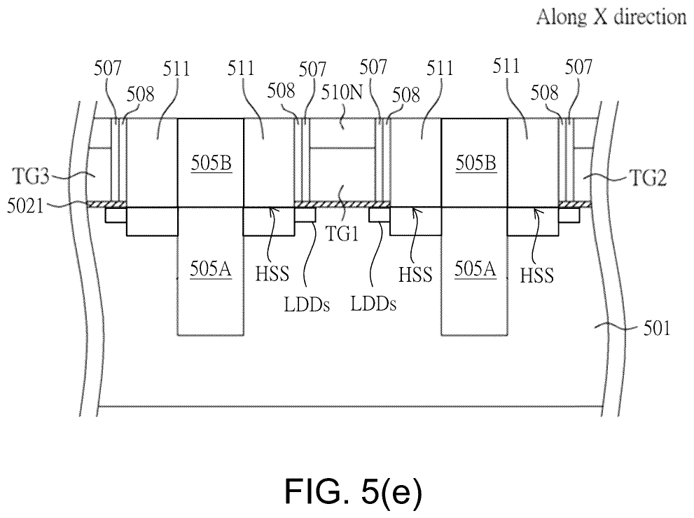

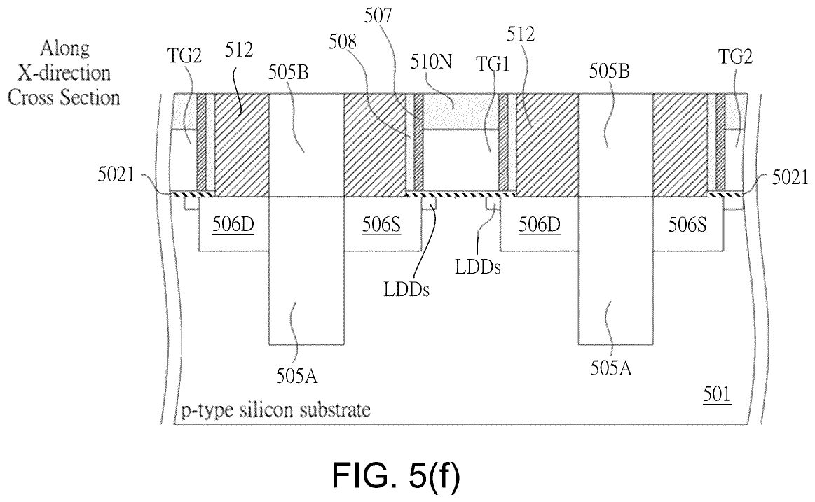

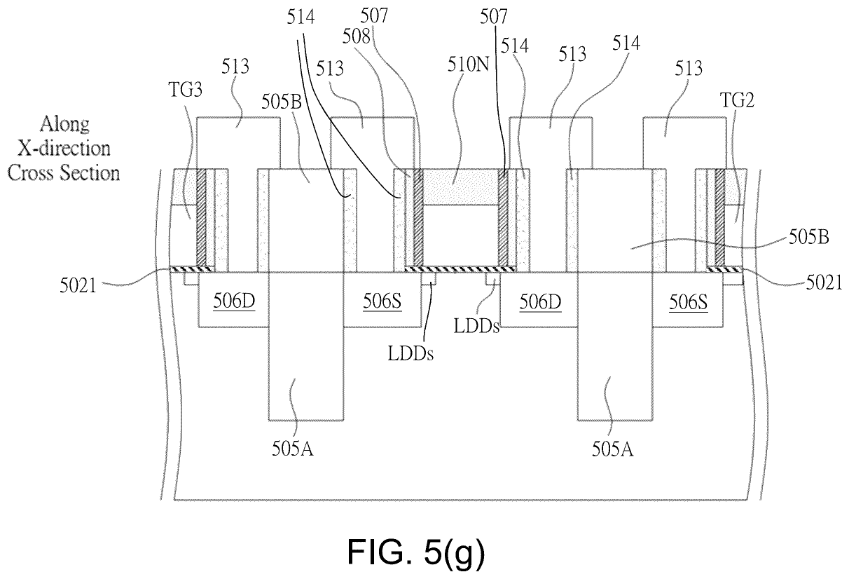

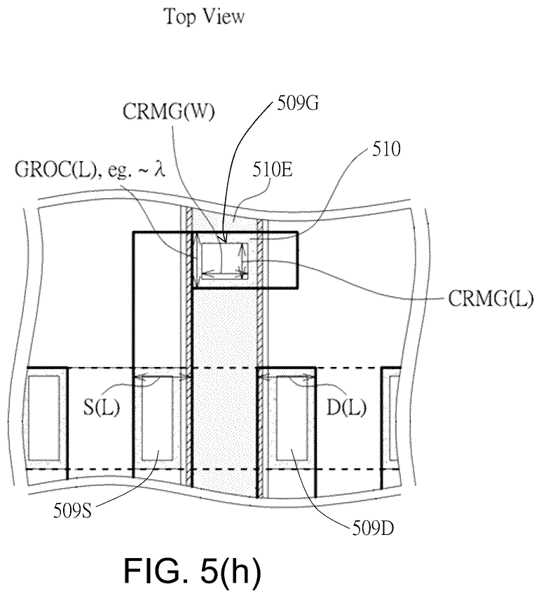

FIG. 5(a) is a top view illustrating a miniaturized metal oxide semiconductor field effect transistor (mMOSFET) 500 used in a SRAM cell structure according to one embodiment of the present disclosure. As shown in FIG. 5, the mMOSFET 500 includes: (1) a gate structure 510 has a length G(L) and a width G(W) and a gate extension region 510E outside the transistor and over the shallow trench isolation region 502, (2) on a left-hand side of the gate structure 510, a source 506S has a length S(L) which is a linear dimension from an edge of the gate structure 510 to an edge of an shallow trench isolation region 502 and a width S(W), (3) on a right-hand side of the gate structure 510, a drain 506D has a length D(L) which is a linear dimension from the edge of the gate structure 510 to the edge of the shallow trench isolation region 502 and a width D(W), (4) at a center of the source 506S, a contact-hole 509S formed by a self-alignment technology has length and width of an opening labeled as C-S(L) and C-S(W), respectively, and (5) similarly at a center of the drain 506D, a contact hole 509D formed by the self-alignment technology has length and width of an opening labeled as C-D(L) and C-D(W), respectively. The length G(L), the length D(L), and the length S(L) could be precisely controlled as small as the minimum feature size A. Furthermore, the length and width of an opening labeled as C-S(L) and C-S(W) or the length and width of an opening labeled as D-S(L) and D-S(W) could be less than A, such as 0.6λ˜0.8λ.

FIGS. 5(b)-5(g) are cross-sectional views illustrating a series of processing structures for forming the mMOSFET 500 as depicted in FIG. 5(a). Firstly, an active region of the mMOSFET is defined by remove parts of silicon material outside the active region to expose a portion of the original horizontal surface of the silicon substrate (“HSS”). A dielectric insulator 5021 is formed. Then, a gate layer and a nitride layer 510N are deposited above the HSS, and the gate layer and the nitride layer 510N are etched to form a plurality of true gates TG1-TG3 of the mMOSFET and a plurality of dummy shield gates DSG. Wherein each one of the dummy shield gates DSG is disposed between to two adjacent ones of the true gates TG1-TG3 with a desired linear distance. As shown in FIG. 5(b), the length of the true gates TG1-TG3 could be as small as λ, the length of the dummy shield gate DSG is also as small as λ, and the distance between the edges of on dummy shield gate DSG to the edge of the adjacent true gates TG1-TG3 is λ as well. In another embodiment, the aforesaid distances could be adjusted or enlarged for manufacturing tolerance.

Then, deposit a spin-on dielectric (SOD) 503 to fill the gaps between adjacent two ones of the dummy shield gates DSG and the true gates TG1-TG3, and then etch back the SOD 503. Form a well-designed gate mask layer 504 by the photolithographic masking technique. Thereafter, utilize the anisotropic etching technique to remove the dummy shield gates DSG, the portions of the nitride layer 510N above the dummy shield gates DSG, the portions of the dielectric insulator 5021 corresponding to the DSG, and the portions of the p-type substrate 501 corresponding to the DSG, so as to form a plurality of opening 5050 extending into the p-type substrate 501 from the HSS (as shown in FIG. 5(c)).

Furthermore, remove the gate mask layer 504, etch the SOD 503, and deposit a plurality of STI-oxide 505A in the plurality of opening 5050 and then etch back. Then, deposit and etch back an oxide layer to form an oxide spacer 507 on the sidewalls of the true gates TG1-TG3, form the lightly doped drains LDDs in the p-type substrate 501, deposit and etch back a nitride layer to form a nitride spacer 508, and remove the portions of the dielectric insulator 5021 not covered by the true gates TG1-TG3, the oxide spacer 507 and the nitride spacer 508, so as to expose portions of the HSS (as shown in FIG. 5(d)).

Moreover, utilize a selective epitaxy growth (SEG) technique to grow intrinsic silicon electrode 511 on the exposed portions of the HSS. Then deposit and etch back a CVD-STI-oxide layer 505B, It is noticed that, the combination of the oxide layer 505B and STI-oxide 505A could be part of the shallow trench isolation (STI) region 502 surrounding the transistor with TG1. The top of the STI region 502 is higher than the HSS, and could be higher than the TG1. Moreover, the STI region 502 surrounds three sides of the intrinsic silicon electrode 511 at this step. Then, remove the intrinsic silicon 511 to reveal the HSS again, and form a source region (n+ source) 506S and a drain region (n+ drain) 506D of the mMOSFET (such as, by etching down the HSS to reveal the side edge (110) of the semiconductor substrate and selectively grow the source/drain). Thus, the source/drain regions are also surrounded by the STI region 502. Since the source region (n+ source) 506S and the drain region (n+ drain) 506D are formed between the true gates TG1-TG3 and the CVD-STI-oxide layer 505B of the STI region 502, the location of which is originally occupied by the dummy shield gates DSG, thus, the length and width of the source region (n+ source) 506S (or a drain region (n+ drain) 506D) could be as small as λ. The opening of the source region (n+ source) 506S (or a drain region (n+ drain) 506D) could be less than λ due to the extra spacer 508, such as 0.8λ. Such openings could be shrunk if further oxide spacer 507 is formed (as shown in FIG. 5(e)).

Additionally, the new SRAM structure makes the first metal interconnection (M1 layer) directly connect the gate structure 510, source region 506S and/or drain region 506D through self-aligned miniaturized contacts without using a conventional contact-hole-opening mask and/or a Metal-0 translation layer for M1 connections. After the source/drain regions are formed, a layer of SOD 512 is deposited to fill the vacancies in the substrate 501 previously occupied by the intrinsic silicon 511, including the openings of the source region (n+ source) 506S (or a drain region (n+ drain) 506D). Then use CMP to make the surface flat (as shown in FIG. 5(f)).

Furthermore, use a well-designed mask and carry out a photo resistance layer (not shown) which results in some stripe pattern (rather than a conventional two-dimensional contact hole pattern) along the X-axis with a separate space of the length GROC(L) to expose the area of gate extension region 510E along the Y-axis. The most aggressive design rules with GROC(L)=λ. Then use an anisotropic etching technique to remove the nitride-cap layer within the exposed gate extension region 510E to reveal the conductive Metal-gate layer of the true gates TG1.

Thereafter, remove the SOD layer 512 so that those opening regions on top of both the source region 506S and the drain region 506D are revealed again. Then deposit a layer of oxide with well-designed thickness and then use an anisotropic etching technique to form spacers 514 on the four sidewalls in opening regions of the source region 506D and the drain region 506D and the exposed gate extension region 510E. Therefore, natural built-up contact-hole openings 509G, 509S and 509D are formed in the exposed gate extension region 510E, the source region 506S and the drain region 506D, respectively.

Finally, form a layer of Metal-1 513 which has the well-designed thickness to fill in the holes of all the aforementioned contact-hole openings 509G, 509S and 509D and result in a smooth planar surface following the topography of the wafer surface. Then use a photolithographic masking technique to create all the connections among those contact-hole openings 509G, 509S and 509D respectively to achieve the necessary Metal-1 interconnection networks. The process for forming of the mMOSFET 500 (as shown in FIG. 5(g)) is accomplished.

FIG. 5(h) shows top view of the mMOSFET 500 as depicted in FIG. 5(g). The vertical length CRMG(L) of the opening 509G in the exposed gate extension region 510E is smaller than the length GROC(L) which could be A.

Because this Metal-1 layer 513 complete the tasks of achieving both the contact-filling and the plug-connection to both gate and source/drain functions as well as a direct interconnection function of connecting all transistors. There is no need to use an expensive and very rigidly controlled conventional contact-hole mask and carrying on the subsequent very difficult process of drilling the contact-hole openings, especially which should be the most difficult challenges in further scaling down the horizontal geometries of billions of transistors. In addition, it eliminates making both a metal plug into the contact-hole openings and a CMP process to achieve a Metal stud with complex integrated processing step (e.g. as definitely required for some leading-edge technology of creating a Metal-Zero structure).

### Embodiment 2 (NuCMOS Transistors-Localize Isolation and Vertical Edges Source/Drain Regions for Shorter Latch Up Distance, and Metal-Semiconductor Junction for Reduced Resistance)

The present embodiment discloses a new SRAM structure in which the n+ and p+ regions of the source and drain regions in the NMOS and PMOS transistors respectively are fully isolated by insulators, such insulators would not only increase the immunity to Latch-up issue, but also increase the isolation distance into silicon substrate to separate junctions in NMOS and PMOS transistors so that the surface distance between junctions can be decreased (such as 3A), so is the size of the SRAM. The following briefly describes a new SRAM structure in which the n+ and p+ regions of the source and drain regions in the NMOS and PMOS transistors respectively are fully isolated by insulators.

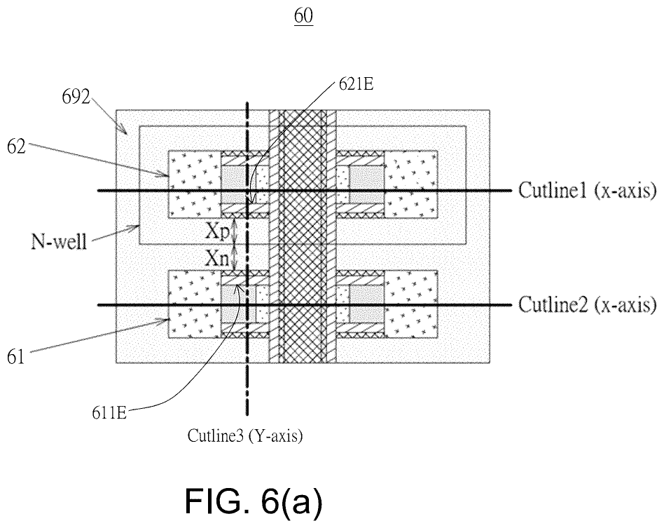

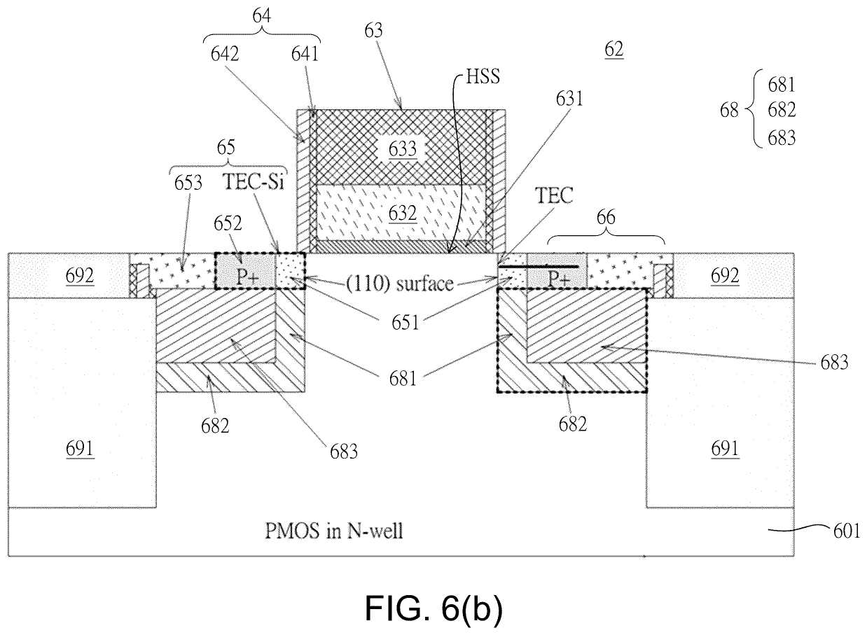

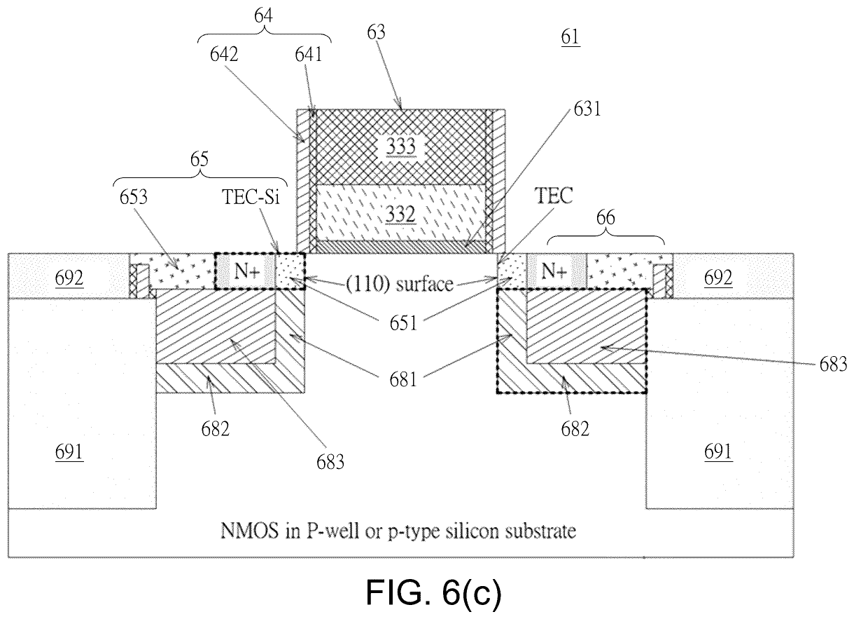

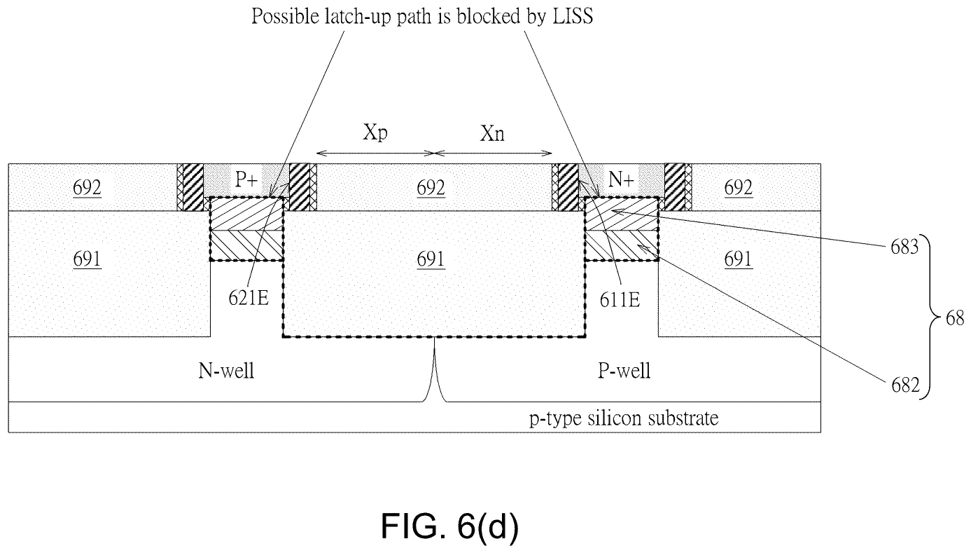

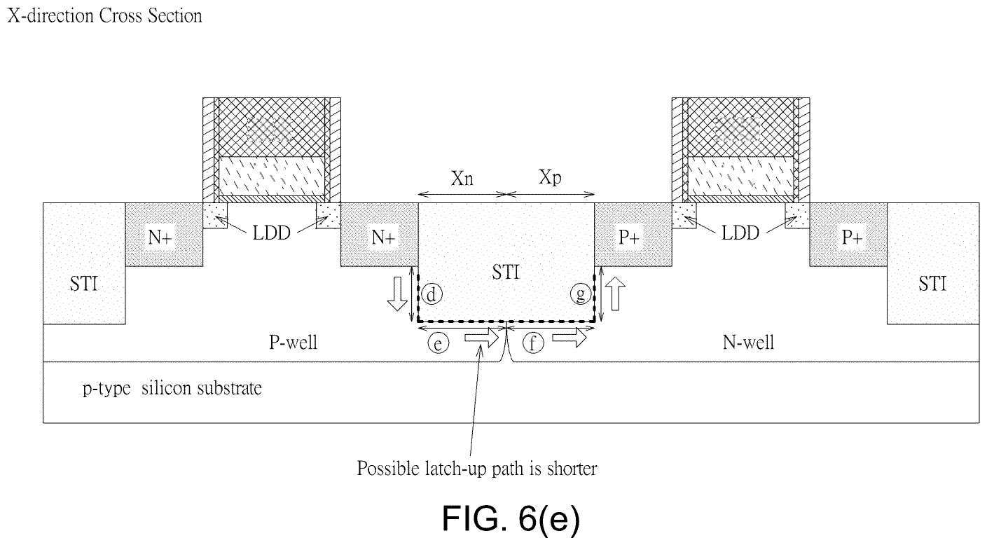

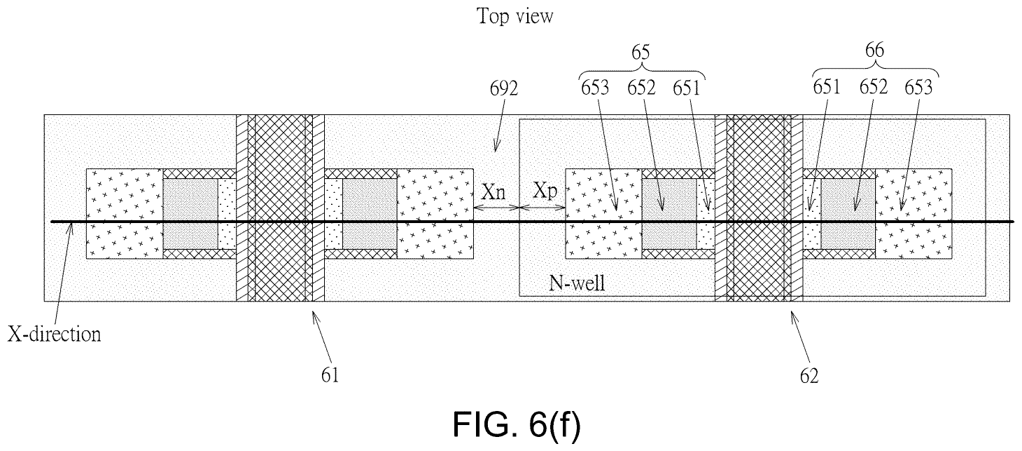

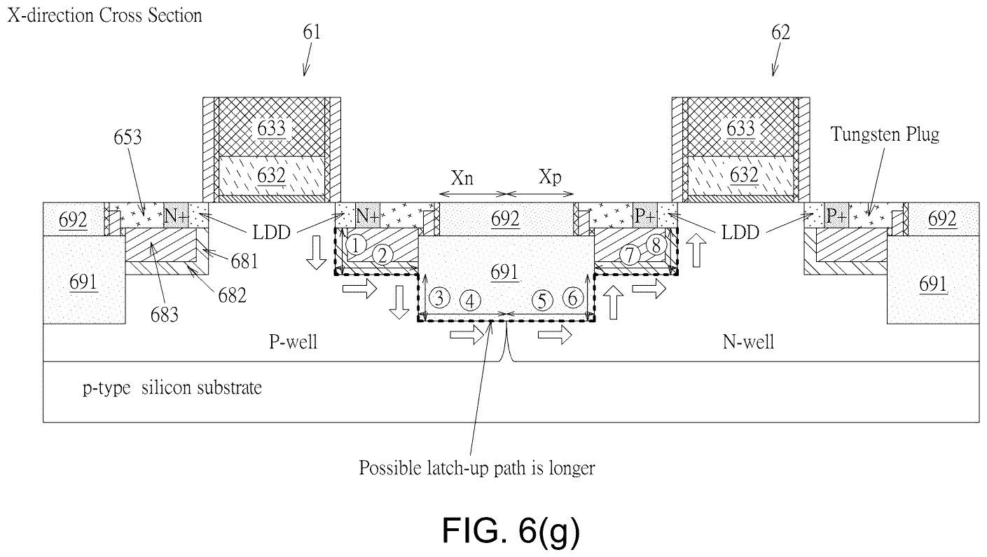

FIG. 6(a) is a top view illustrating a combination of a PMOS transistor 62 and a NMOS transistor 61 used in a SRAM cell structure according to one embodiment of the present disclosure. FIG. 6(b) is a cross-sectional view illustrating the PMOS transistor 62 taken along the cutline 1(X-axis) in FIG. 6(a). FIG. 6(c) is a cross-sectional view illustrating the NMOS transistor 61 taken along the cutline 2 (X-axis) in FIG. 6(a). FIG. 6(d) is a cross-sectional view illustrating the PMOS transistor 62 and the NMOS transistor 61 taken along the cutline 3(Y-axis) in FIG. 6(a).

The gate structure 63 comprising a gate dielectric layer 631 and gate conductive layer 632 (such as gate metal) is formed above the horizontal surface or original surface of the semiconductor substrate (such as silicon substrate, or semiconductor substrate with multiple superlattice structure Si/SiGe for gate all around GAA transistors in which the horizontal surface or original surface will be the top of the multiple superlattice structure). A dielectric cap 633 (such as a composite of oxide layer and a Nitride layer) is over the gate conductive layer 632. Furthermore, spacers 64 which may include a composite of an oxide layer 641 and a Nitride layer 642 is used to over sidewalls of the gate structure 63. Trenches are formed in the semiconductor substrate and under the horizontal surface or original surface of the semiconductor substrate. Then, a localized isolation 68 (such as nitride or other high-k dielectric material) is located in one trench and positioned under the source region, and another localized isolation 68 is located in another trench and positioned under the drain region. Such localized isolation 68 is below the horizontal silicon surface (HSS) of the silicon substrate 601 and could be called as localized isolation into silicon substrate(LISS) 68. The LISS 68 could be a thick Nitride layer or a composite of dielectric layers. For example, the localized isolation or LISS 68 could comprise a composite localized isolation which includes a L shape isolation with an oxide layer (called Oxide-3V layer 681) covering at least a portion sidewall of the trench and another oxide layer (Oxide-3B layer 682) covering at least a portion bottom wall of the trench. The Oxide-3V layer 681 and Oxide-3B layer 682 could be formed by thermal oxidation process, such that the edge of the Oxide-3V is well-controlled, such as aligned with the edge of the gate conductive later 632. The composite localized isolation 68 further includes a nitride layer 683 (called as Nitride-3) being over the Oxide-3B layer 682 and contacting with the Oxide-3V layer 681. It is mentioned that the nitride layer 683 or Nitride-3 could be replaced by any suitable insulation materials as long as the Oxide-3V layer 681 remains most as well as being designed. Afterward, part of the Oxide-3V layer 681 higher than the top of the nitride layer 683 is etched to reveal the (110) orientation surface of the substrate. Then, all or at least part of the source region 65 and drain region 66 are positioned in the corresponding trenches, respectively. The source (or drain) region in the PMOS transistor 62 may include selectively grown P+ region or other suitable doping profile regions (such as gradual or stepwise change from LDD P− region and P+ region) which are grown from the (110) surface. It is noticed that the edge of the LDD region could be well controlled and aligned with the edge of the gate conductive region 632 with the help of the edge of the Oxide-3V layer 681, thus, the GIDL is reduced in the present invention. Furthermore, the STI (Shallow Trench Isolation) region could comprise a composite STI 69 which includes a STI-1 layer 691 and a STI-2 layer 692, wherein the STI-1 layer 691 and the STI-2 layer 692 could be made of thick oxide material by different process, respectively. As mentioned, the STI region could be raised higher than the original or horizontal silicon surface (HSS) of the semiconductor substrate, and as high as the top of the gate structure 63 to surround or confine the grown source/drain regions between the gate structure 63 and the STI region 69, especially the STI region 69 could surround three sides of the grown source/drain regions.

Moreover, the source region 65 (or drain region 66) could comprise a composite source region 65 and/or drain region 66. For example, in the PMOS transistor 62, the composite source region 65 (or drain region 66) at least comprises a lightly doped drain(LDD) 651 and a heavily P+ doped region 652 in the trench. Especially, as previously mentioned, it is noted that the lightly doped drain(LDD) 651 abuts against an exposed silicon surface with a uniform (110) crystalline orientation. The exposed silicon surface has its vertical boundary with a suitable recessed thickness in contrast to the edge of the gate structure, which is labeled as TEC (Thickness of Etched-away Transistor-body Well-Defined to be the Sharp Edge of Effective Channel Length). The exposed silicon surface is substantially aligned with the gate structure. The exposed silicon surface could be a terminal face of the channel of the transistor.

As previously mentioned, the lightly doped drain(LDD) 651 and the heavily P+ doped region 652 could be formed based on a selective epitaxial growth (SEG) technique (or other suitable technology which may be atomic layer deposition (ALD) or selective growth ALD (SALD) to grow silicon from the exposed TEC area which is used as crystalline seeds to form new well-organized (110) lattice across the LISS region which has no seeding effect on changing (110) crystalline structures of newly formed crystals of the composite source region 65 or drain region 66. Such newly formed crystals (including the lightly doped drain(LDD) 651 and the heavily P+ doped region 652) could be named as TEC-Si. In one embodiment, the TEC is aligned or substantially aligned with the edge of the gate structure 63, and the length of the LDD 651 is adjustable, and the sidewall of the LDD 651 opposite to the TEC could be aligned with the sidewall of the spacer 64.

Similarly, the TEC-Si (including the LDD region and the heavily N+ doped region) of the composite source/drain region for the NMOS transistor 61 is shown in FIG. 6(c). The composite source (or drain) region could further comprise some tungsten (or other suitable metal materials) plugs 653 formed in a horizontal connection to the TEC-Si portion for completion of the entire source/drain regions, the active channel current flowing to future metal interconnection such as Metal-1 layer is gone through the LDD 651 and heavily-doped conductive region 652 to tungsten 653 (or other metal materials) which is directly connected to Metal-1 by some good Metal-to-Metal ohmic contact with much lower resistance than the traditional Silicon-to-Metal contact. As previously mentioned, since the STI region could be raised higher than the original or horizontal silicon surface (HSS) of the semiconductor substrate, and as high as the top of the gate structure 63 to surround or confine three sides of the grown source/drain regions, there is a self-aligned contact holes formed above the selectively grown source/drain regions, as shown in FIG. 5(g), therefore, the tungsten 653 or other composite metal material (TiN+W) could be deposited in the self-aligned contact holes to contact the top of the grown source/drain regions which extend to the STI region 69, or to contact the top and most lateral sidewall of the grown source/drain regions which do not extend to the STI region 69, such that the contact resistance could be reduced.

Moreover, As shown in FIG. 6(a) and FIG. 6(d), the grown or epitaxial source (drain) region extending along the x axis of the PMOS transistor 62 has an edge surface 621E, and the grown source (drain) region extending along the x axis of the NMOS transistor 61 has an edge surface 611E, and the edge surface 621E faces to the edge surface 611E, and is also parallel or substantially parallel to the edge surface 611E. Both the edge surface 611E and edge surface 621E may be vertical or substantially vertical to the original or horizontal surface of the substrate.

As shown in FIG. 6(d), there exists a composite localized isolation (or the LISS 68) between the bottom of the P+ source/drain region of the PMOS transistor 62 and the n-type N-well, so is another composite localized isolation (or the LISS 68) between the bottom of the N+ source/drain region of the NMOS transistor 61 and the p-type P-well or substrate 601. The advantage is clearly shown that the bottom of the n+ and p+ regions are fully isolated by insulators in this newly invented CMOS structure, that is, the possible latch-up path from the bottom of the P+ region of the PMOS transistor 62 to the bottom of the N+ region of the NMOS transistor 61 is totally blocked by the LISS. Thus, the latch up distance between the PMOS and NMOS transistors could be reduced.

On the other hand, in the traditional CMOS structure the n+ and p+ regions are not fully isolated by insulators as shown in FIG. 6(e), the possible Latch-up path exists from the n+/p junction through the p-well/n-well junction to the n/p+ junction includes the lengths d, e, f, and g. Thus, from device layout point of view, the reserved edge distance (Xₙ+Xₚ) between NMOS and PMOS in FIG. 6(d) of the present invention could be smaller than that in FIG. 6(e) in the conventional design. For example, the reserved edge distance (Xₙ+Xₚ) could be around 2˜4λ, such as 3λ.

The other combination structure of the new PMOS 62 and new NMOS 61 is shown in FIG. 6(f) which is a top view, and FIG. 6(g) is a diagram illustrating a cross section of the combination of the new PMOS 62 and new NMOS 61 along the cutline (X-axis) in FIG. 6(f). As shown in FIG. 6(g), it results in a much longer path from the n+/p junction through the p-well (or p-substrate)/n-well junction to the n/p+ junction. The possible Latch-up path from the LDD-n/p junction through the p-well/n-well junction to the n/LDD-p junction includes the length \textcircled{1}, the length \textcircled{2} (the length of the bottom wall of one LISS region), the length \textcircled{3}, the length \textcircled{4}, the length \textcircled{5}, the length \textcircled{6}, the length \textcircled{7}(the length of the bottom wall of another LISS region), and the length \textcircled{8}marked in FIG. 6(g). On the other hand, in traditional CMOS structure which combines PMOS and NMOS structure shown in FIG. 6(e), the possible Latch-up path from the n+/p junction through the p-well/n-well junction to the n/p+ junction just includes the length d, the length e, the length f, and the length g. Such possible Latch-up path of FIG. 6(g) is longer than that in FIG. 6(e). Therefore, from device layout point of view, the reserved edge distance (Xₙ+Xₚ) between NMOS and PMOS in FIG. 6(g) could be smaller than that in FIG. 6(e). For example, the reserved edge distance (Xₙ+Xₚ) could be around 2˜4λ, such as 3λ.

Another embodiment for forming of the NMOS transistor 700 includes steps as follows. Firstly, an active region pattern having a semiconductor surface 701S is define by removing parts of silicon material of a semiconductor substrate 701 using a photolithographic masking technique to create the trenches 701A and 701B. An oxide layer 702A is first deposited to fully fill the trenches 701A and 701B and then etched back, such that the remaining oxide layer 702A is below a semiconductor surface 701S of the active region. Then, a dielectric insulator 703 is formed covering on the semiconductor surface 701S and the remaining oxide layer 702A. A gate structure 704 including a gate layer 704A and a nitride layer 704B are formed above the dielectric insulator 703 in the active region of the semiconductor substrate 701.

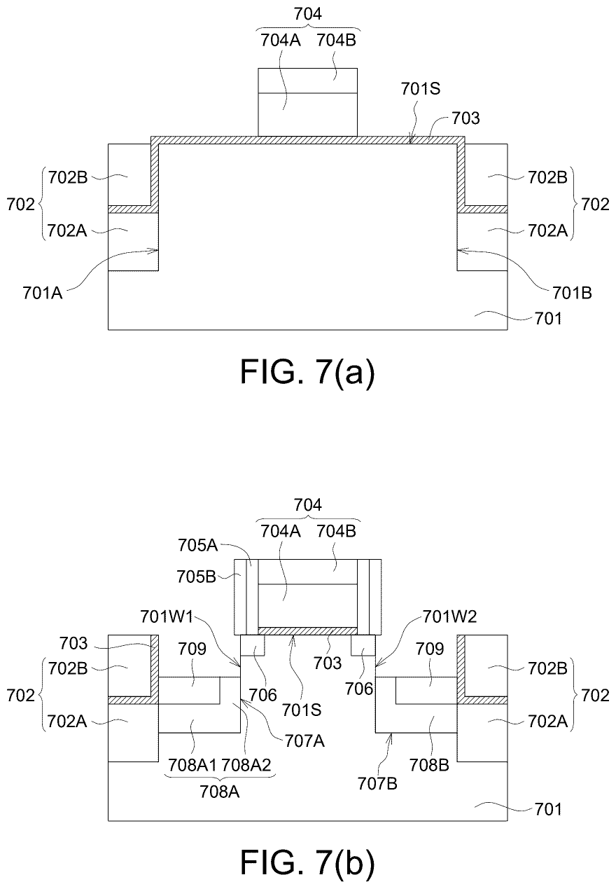

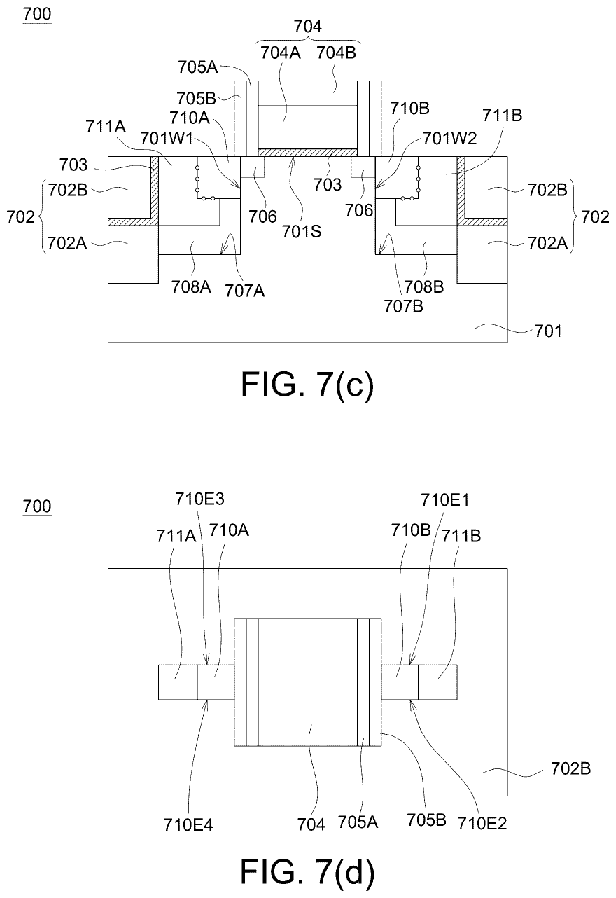

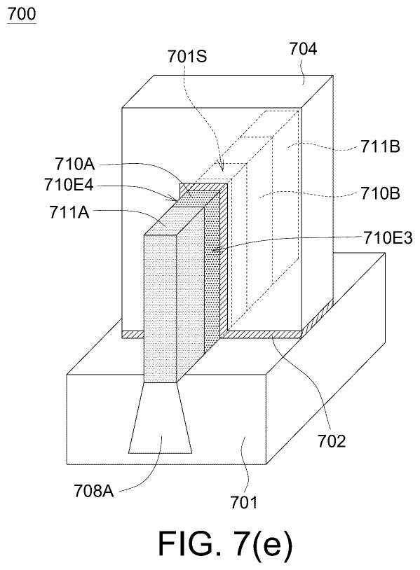

Then, an oxide layer 702B with enough thickness is deposited to fill in vacancies and above the trenches 701A and 701B, and use a chemical and mechanical polishing (CMP) and/or an etch-back technique to planarize the oxide layer 702B to a top of the semiconductor surface 701S or a top of the dielectric insulator 703 (or as mentioned the top of the oxide layer 702B could be higher than the semiconductor surface 701S, or as high as the top of the gate structure 704), wherein the oxide layers 702A and 702B as well as the portions of the dielectric insulator 703a all formed in the trenches 701A and 701B are combined to form a trench isolation layer 702 which is also called the deep shallow trench isolation structures (or just called deep oxide isolation “DOI”) (as shown in FIG. 7(a)).

An oxide spacer layer 705A is formed to cover the sidewalls of the gate structure 704. Then, lighted doped zones are formed in the p-type substrate 701 and rapid thermal annealing (RTA) is performed on the lighted doped zones to form the n-type lightly doped drains (NLDDs) 706. A nitride spacer layer 705B is formed to cover the oxide spacer layer 705A and the NLDDs 706.

The oxide spacer layer 705A, the nitride spacer layer 705B and the deep shallow trench isolation structures (the trench isolation layer 702) can act as the mask, the portion of the dielectric insulator 703 not covered by the mask can be removed to expose the semiconductor surface 701S. Then, the exposed silicon materials can be etched down from the semiconductor surface 701S by the anisotropic etching technique to form the first concave 707A and the second concave 707B.

Oxide layers are respectively grown in the first concave 707A and the second concave 707B to form a first guard isolation layer 708A and a second isolation layer 708B, respectively. Metal layer (e.g. tungsten) 709 is deposited into the first concave 707A and the second concave 707B, respectively. In addition, the anisotropic etching technique is utilized to etch down the metal layer 709 inside the first concave 707A and the second concave 707B to a well-designed height to make a top of the metal layer 709 lower than the semiconductor surface 701S. Then, the etched metal layer 709 can act as a blocking base to remove the portions of the first guard isolation layer 708A and the second guard isolation layer 708B higher than the etched metal layer 709, such that the portion of the silicon sidewall 701W1 of the first concave 707A and a portion of the silicon sidewall 701W2 of the second concave 707B can be exposed, as shown in FIG. 7(b).

To take the exposed silicon sidewall 701W1 of the first concave 707A and the exposed silicon sidewall 701W2 of the second concave 707B as seeding materials (wherein the exposed silicon sidewalls 701W1 and 701W2 are below the semiconductor surface 701S), a selective epitaxy growth (SEG) technique (or an atomic layer deposition (ALD) growth technique) is utilized to grow laterally the n+ in-situ doping first semiconductor region 710A and the n+ in-situ doping second semiconductor region 710B from the exposed silicon sidewall 701W1 and 701W2 respectively, resulting in an n+ semiconductor junction existing between the first semiconductor region 710A and the p-type substrate 701 and an n+ semiconductor junction existing between the second semiconductor region 710B and the p-type substrate 701. In addition, as mentioned, the growing silicon is surrounded by the shallow trench isolation structures.

Because the present invention grows laterally silicon electrodes, i.e. the first semiconductor region 710A and the second semiconductor region 710B, based on exposed sidewalls of the p-type substrate for NMOS (or exposed sidewalls of the n-type substrate for PMOS), all the techniques of growing drain and source electrodes in the state-of the-art tri-gate, FinFET, GAA, or other fin-structure type transistor can be employed to the present invention, such as any strain related material or process can enhance a transistor mobility and speed, and later form a silicide layer into a top region of electrodes of the transistor to make the top region of the electrodes have a better interface with Ohmic contact, and so on.

The metal layer 709 formed into the first concave 707A and the second concave 707B could be optionally removed. Then, the layer of composite metal material (CMM) is deposited into the first concave 707A and the second concave 707B to contact the bottom surface and the most lateral sidewall of the first semiconductor region 710A and the second semiconductor region 710B, e.g. in one embodiment the composite metal material may include a silicide material covering the first/second semiconductor regions 710A/710B, a TiN buffer layer (kind of core metal column) covering the silicide material, and a tungsten layer filling in the first/second concaves 707A/707B. The TiN buffer layer is deposited into the first concave 707A and the second concave 707B to provide good interface with the silicide layer on the sidewalls of the first semiconductor region 710A and the second semiconductor region 710B, respectively, and subsequently the tungsten layer is deposited into the first concave 707A and the second concave 707B. The composite metal material (CMM) could be the first metal containing region 711A and the second metal containing region 711B, wherein the TiN buffer layer contacts to the silicide layer and the core metal column (CMC). In addition, the CMM is filled into not only the first concave 707A and the second concave 707VB but also all vacancies above the first concave 707A and the second concave 707B, and the anisotropic etching technique is utilized to remove some extra CMM until height of the CMM can be leveled up to the top of the semiconductor surface 701S, or even higher than the semiconductor surface 701S to cover the top surface of the first semiconductor region 710A and the second semiconductor region 710B

As shown in FIG. 7(c), one sidewall of the first metal containing region 711A contacts to the lateral sidewall of the first semiconductor region 710A, and other three sidewalls of the first metal containing region 711A are isolated by the deep shallow trench isolation structure 702/the first guard isolation layer 708A; the bottom of the first metal containing region 711A is isolated by the first guard isolation layer 708A as well. Similarly, one sidewall of the second metal containing region 711B contacts to the lateral sidewall of the second semiconductor region 710B, and other three sidewalls of the second metal containing region 711B are isolated by the deep shallow trench isolation structure 702/the second guard isolation layer 708B; a bottom of the second metal containing region 711B is isolated by the second guard isolation layer 708B as well.

In addition, taking the first metal containing region 711A and the first guard isolation layer 708A as an example, as shown in FIG. 7(b) and(c), the first guard isolation layer 708A includes the horizontal guard isolation portion 708A1 and the vertical guard isolation portion 708A2, wherein the vertical guard isolation portion 708A2 contacts to the sidewall of the first metal containing region 711A and the bottom of the first semiconductor region 710A, and the horizontal guard isolation portion 708A2 contacts to the bottom of the first metal containing region 711A. Therefore, the first metal containing region 711A is prevented from directly contacting to the p-type substrate 701 by the first guard isolation layer 708A. In addition, because a top of the deep shallow trench isolation structure 702 is up to the top of the semiconductor surface 701S or the top of the gate structure 704, the deep shallow trench isolation structure 702 can separate the NMOS transistor 700 from neighboring transistors.

Furthermore, taking the first metal containing region 711A, the first semiconductor region 710A, and the NLDD 706 as an example, as shown in FIG. 7(c), a vertical length of the first semiconductor region 711A in touch with the NLDD 706 can be adjusted as a design tradeoff for desirable requirements of parameters of the NMOS transistor 700, such as width of the gate layer 704A, targeted allowable leakage-current magnitude including (drain Induced Barrier Lowering, DIBL), drain-to-source sub-channel conduction current for somewhat deteriorated short-channel effect, drain (source)/substrate junction leakages, and so on. A top of the first metal containing region 710A could be designed to have a metal landing pad (MLP) function for receiving the metal-1 interconnection with much reduced border edges of openings to the first semiconductor region 710A, which thus allows more tightened design rules on the metal-1 connection to the first semiconductor region 710A.

FIG. 7(d) is a top view of the NMOS transistor 700 as depicted in FIG. 7(c) after the SEG grown semiconductor and CMM are completed. As shown in FIGS. 7(d) and 7(e), the laterally grown n+ silicon (i.e. the first semiconductor region 710A) and CMM (i.e. the first metal containing region 711A) are formed in the rectangular first concave (not shown), and the laterally grown n+ silicon (i.e. the second semiconductor region 710B) and CMM (i.e. the second metal containing region 711B) are formed in the second concave (not shown). The laterally grown n+ silicon and CMM are surrounded by STI oxide (i.e. trench isolation layer 702 including the oxide layers 702A and 702B), and the laterally grown n+ silicon 710B at least has two edge surfaces 710E1 and 710E2 vertical or substantially vertical to the original surface of the substrate, and the laterally grown n+ silicon 710A at least has two edge surfaces 710E3 and 710E4 vertical or substantially vertical to the original surface of the substrate. So are the first metal containing region 711A and the second metal containing region 711B.

The aforesaid steps would be implemented for the fin-structure transistor produced under 12 nm (or lower) semiconductor manufacture processes. For example, the active region of the NMOS transistor 700 can be a fin-structure or GAA transistor. According to one embodiment of the present disclosure, the 6T SRAM cell structure includes a plurality of transistors with the same structure identical to that of the NMOS transistor 700, separated from each other by the trench isolation layer 702 and covered by the same gate structure 704 and the source/drain regions of the transistors (e.g. NMOS transistors 700) configure multiple fingers or GAA structures.

FIG. 7(e) is a perspective view of the NMOS transistor 700 as depicted in FIG. 7(d). Since the left-hand side (including the first semiconductor region 710A and the first metal containing region 711A) and the right-hand side (including the second semiconductor region 710B and the second metal containing region 711B) of each finger or GAA structure are formed in the rectangular concaves (first concave 707A and the second concave 707B) with three sidewalls surrounded by the trench isolation layer 702 which may restrict the laterally growth of the n+ silicon (the first/second semiconductor region 710A/710B and the CMM (the first/second metal containing region 711A/711B), thus the left-hand side and right-hand side of each finger or GAA transistors are rectangular-shaped, respectively. Meanwhile, the bottom of each rectangular concave is covered either by the first guard isolation layer 708A or by the guard isolation layer 708B.

### Embodiment 3 (OPCMOS Transistor with Diamond-Shaped S/D without Raised STI Region)

This embodiment discloses a FinFET/GAA transistor 800 used in a SRAM cell structure, especially used in a 6T SRAM cell structure. In the present embodiment, the structure of the FinFET/GAA transistor 800 is similar to that of the NMOS transistor 700 as depicted in FIGS. 7(e) and 7(f), except that the left-hand side and right-hand side (or source/drain regions) of the FinFET/GAA transistor 800 are not formed in the concaves with three sidewalls surrounded by STI oxide.

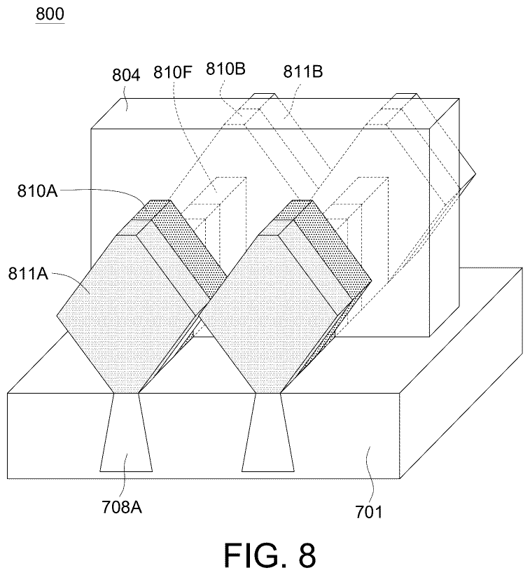

For example in FIG. 8, the FinFET/GAA transistor 800 has a plurality of fin structures or superlattice structures defined in a semiconductor substrate 801 by STI region (not shown) and source/drain regions in-situ grown from the lateral sidewalls of the fin structures or superlattice structures 801F by a selective epitaxy growth (SEG) technique (or an atomic layer deposition (ALD) growth technique). The multiple fin structures or superlattice structures are separated from each other and covered by a gate structure 804 (including a gate dielectric layer and a gate electrode (not shown)). In the present embodiment, each terminal of the fin structure or superlattice structure 801F provides seed regions for selective grown LDD regions and highly doped regions. For example, the left-hand side of each fin structure or superlattice structure respectively include a lightly doped semiconductor region (e.g., an epitaxy silicon N-LDD region for NMOS) 810A laterally grown from one edge of each fin structure or superlattice structure 810F and a heavily doped semiconductor region (e.g., an epitaxy silicon N+ region for NMOS) 811A grown from the lateral edge of the lightly doped semiconductor region 810A; the right-hand side of each fin structure or superlattice structure 810F respectively also includes a lightly doped semiconductor region 810B laterally grown from another edge of each fin structure or superlattice structure 801F and a heavily doped semiconductor region 811B grown from the lateral edge of the lightly doped semiconductor region 810B. Meanwhile, the bottom of each finger is covered either by the guard isolation layer 808 as previously mentioned.

Because the two N+ semiconductor regions 811A and 811B in the FinFET/GAA transistor 800 formed by SEG technique are not limited by the STI oxide region, those two heavily doped epitaxy regions 811A and 811B may gradually expand to separately form mushroom-shaped (or diamond-shaped) semiconductor regions, and these two heavily doped semiconductor regions 811A and 811B may finally be connected together to become the source/drain of one FinFET/GAA transistor 800. Thus, in one example, the width of each fin structure/superlattice structure 801F is 6 nm, the width of the STI region (not shown) between the two independent fin structures/superlattice structures could be 25 nm, and the width of the STI region between this convention FINFET and another same convention FINFET is 25 nm as well. Therefore, the pitch distance between two FINFETs/GAA transistors 800 is 62 nm. This type FinFETs/GAA transistors 800 with NMOS and PMOS could be named as OPCMOS transistors which utilizes the technologies described on Embodiment 1 and embodiment 2 except the raised STI region(and/or metal-semiconductor junctions). On the other hand, the FinFETs/GAA transistors utilizes all the technologies described on Embodiment 1 and embodiment 2 (including the raised STI region) could be named as NuCMOS transistors.

### Embodiment 4 (UGI for Signal Distribution or Heat Dissipation in Composite STI Region)

Furthermore, in traditional SRAM, the metal wires for high level voltage VDD and low level voltage VSS (or Ground) are distributed above the original silicon surface of the silicon substrate, and such distribution will interfere with other metal wires for the word-line (WL), bit-lines (BL and BL Bar), or other connection metal lines if there is no enough spaces among those metal wires. The present invention discloses a new SRAM structure in which the metal wires for high level voltage VDD and/or the low level voltage VSS, and/or bit-lines (BL and BL Bar) could be distributed under the original silicon surface of the silicon substrate, thus, the interference among the size of the contacts, among layouts of the metal wires connecting the word-line (WL), bit-lines (BL and BL Bar), high level voltage VDD, and low level voltage VSS, etc. could be avoided even the size of the SRAM cell is shrunk. For example, as shown in FIG. 6(g), in the drain region of the PMOS 62, the tungsten or other metal materials 653 is directly coupled to the N-well which is electrically coupled to VDD. On the other hand, in the source region of the NMOS 61, the tungsten or other metal materials 653 is directly coupled to the P-well or P-substrate which is electrically coupled to Ground. Thus, the openings for the source/drain regions which are originally used to electrically couple the source/drain regions with metal layer 2 or metal layer 3 for VDD or Ground connection could be omitted in the new SRAM structure.

This embodiment discloses a semiconductor circuit 900 including asymmetric spacers along the sidewalls of the active regions and underground interconnection lines (such as, an underground bit line (UGBL) or other conduction line) between the asymmetric spacers and below the silicon surface (HSS) and within STI region which surround the active regions. The following introduces alternative processes to form such asymmetric spacers and underground interconnection lines.

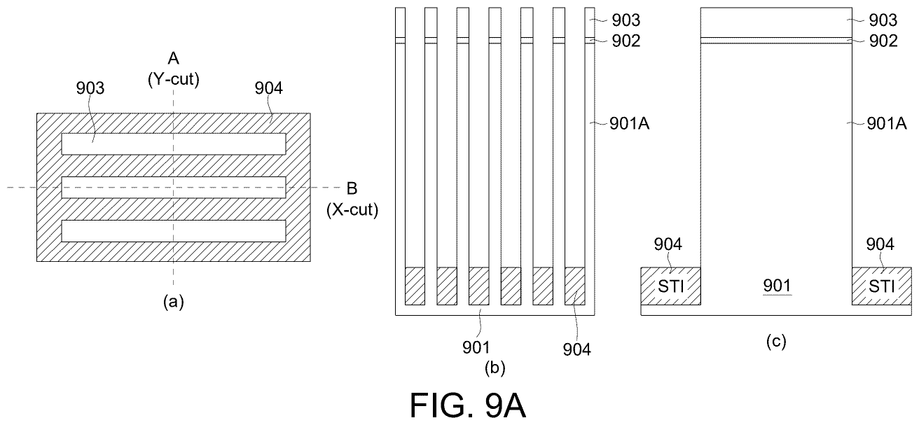

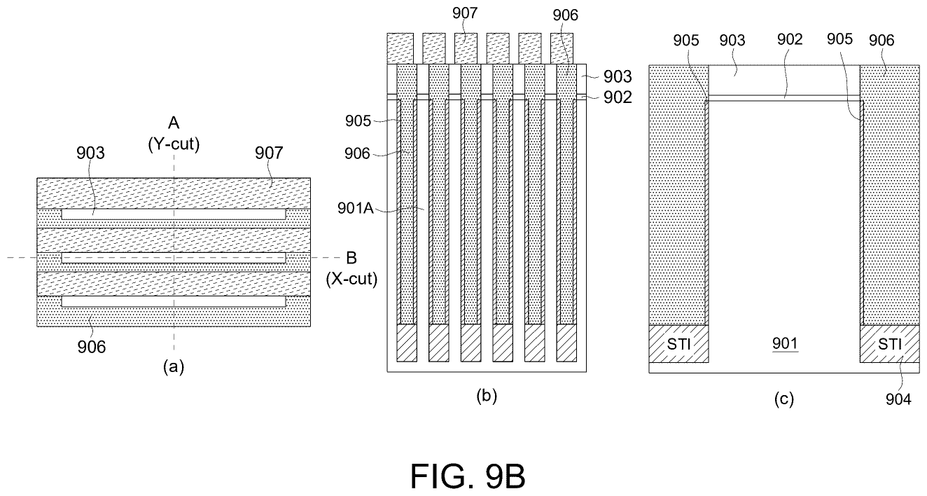

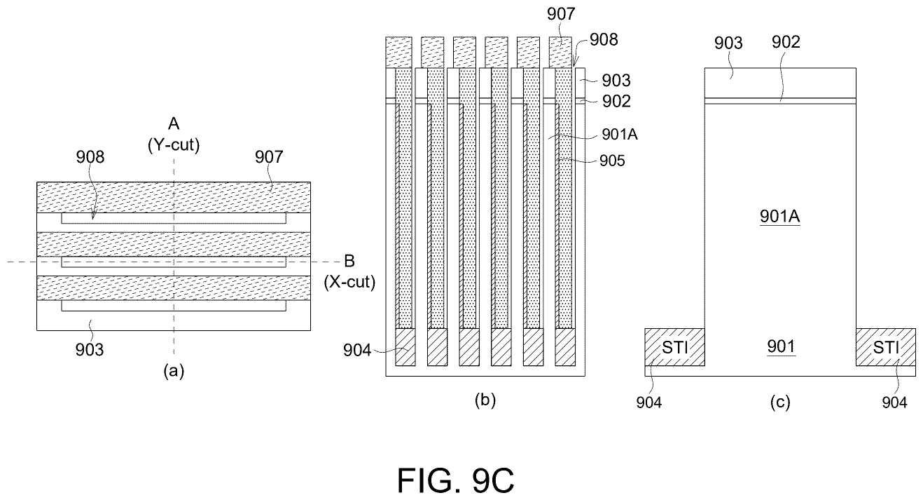

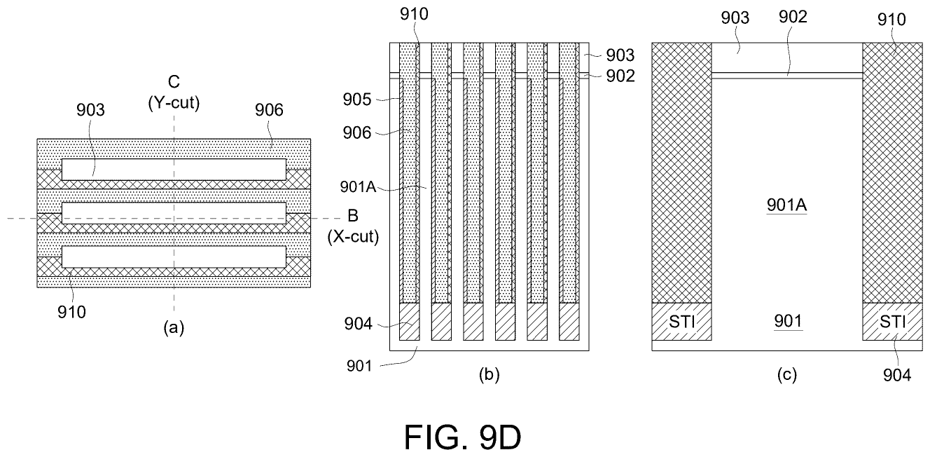

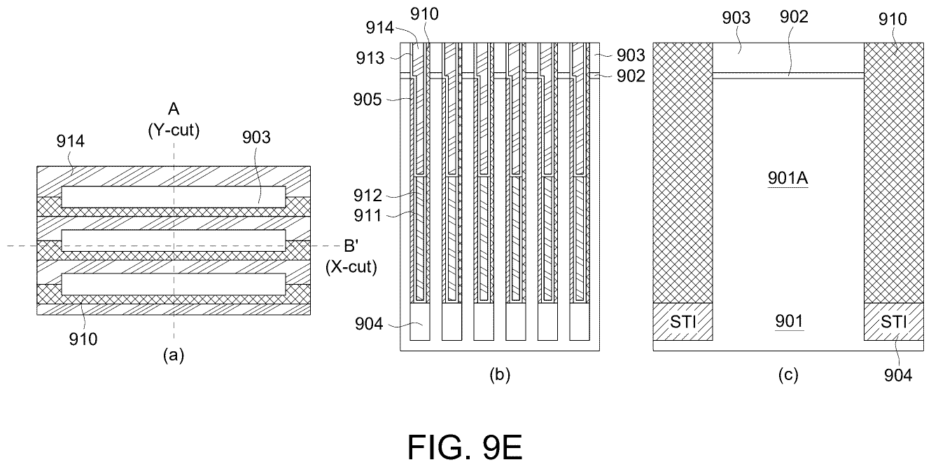

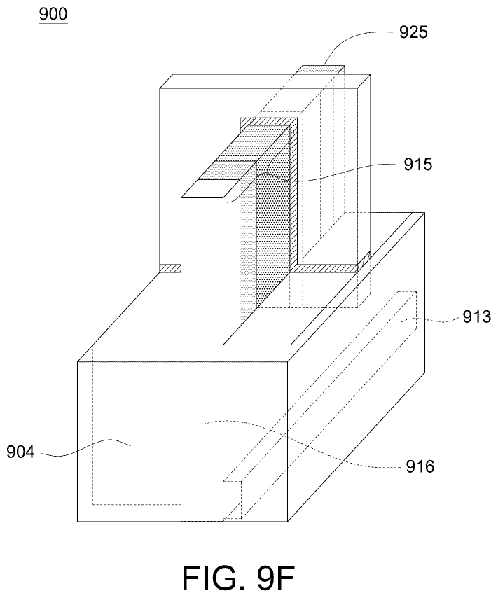

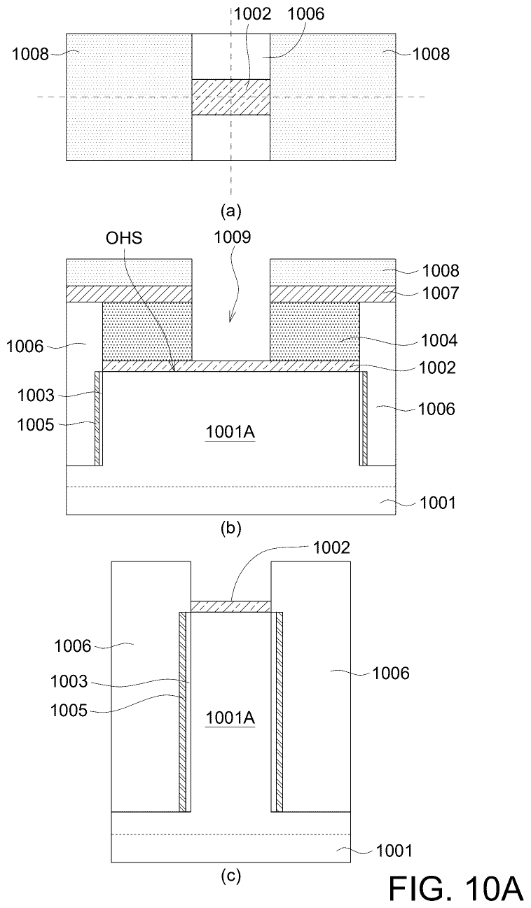

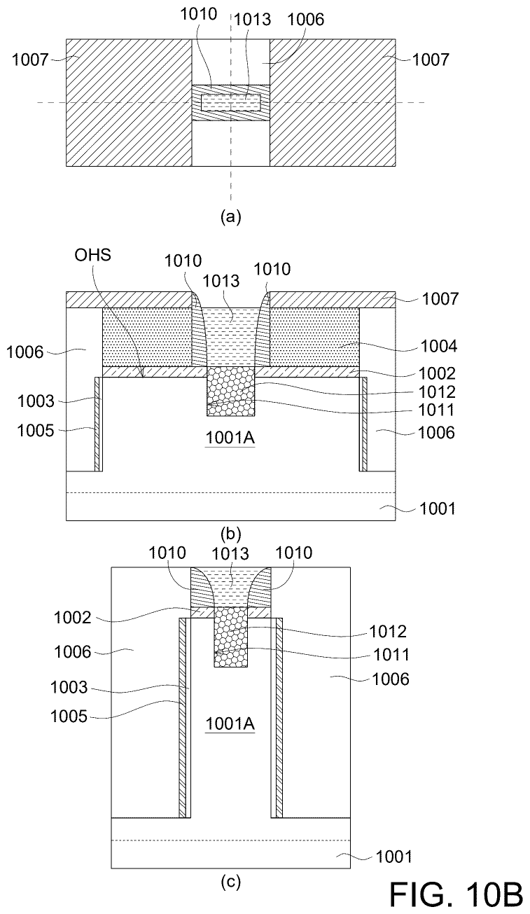

First of all, a pad-oxide layer 902 and a pad-nitride layer 903 are deposited in sequence on a semiconductor substrate 901, and portions of the semiconductor substrate 901 are removed and an oxide layer is deposited and etched back to form shallow trench isolation (STI) regions 904 and define a plurality of active regions 901A (such as, a plurality of fin structures). FIG. 9A(c) is a top view illustrating the temporary structure after the STI regions 904 are formed; FIG. 9A(a) is a cross-sectional view taken along Y-cut as shown in FIG. 9A(c); and FIG. 9A(b) is a cross-sectional view taken along X-cut shown as shown in FIG. 9A(c).

Thereafter, thermal oxide layers 905 are grown along the revealed sidewalls of the active regions 901A. Then, SOD material 906 is deposited to fulfill the gaps between the active regions 901A, and the SOD material 906 is then planarized by CMP process. Afterward, a photo-resistance layer 907 is formed and patterned to cover portion (such as ½) of the active region 901A and reveal portion of the SOD material 906. FIG. 9B(a) is a top view illustrating the processing structure after the SOD material 906 and the photo-resistance layer 907 are formed. FIG. 9B(b) is a cross-sectional view taken along Y-cut as shown in FIG. 9B(a); and FIG. 9B(c) is a cross-sectional view taken along X-cut shown as shown in FIG. 9B(a).

Then, the uncovered SOD material 906 and the thermal oxide 905 under the uncovered SOD material 906 are removed to form narrow slots 908. It is noticed that, after the uncovered SOD material 906 and the thermal oxide 905 under the uncovered SOD material 906 are removed, the narrow slot 908 reveals one sidewall of the active region 901A. FIG. 9C(a) is a top view illustrating the processing structure after the STI regions 904 are formed; FIG. 9C(b) is a cross-sectional view taken along Y-cut as shown in FIG. 9C(a); and FIG. 9C(c) is a cross-sectional view taken along X-cut as shown in FIG. 9C(a).

After the patterned photo-resistance 907 is removed, SiOCN material 910 is deposited within the narrow slots 908 and planarized. Therefore, asymmetric spacers which include different materials (such as the oxide spacer 905 and the SiOCN spacer 910) within STI region 904 are formed. In another view, such asymmetric spacers also cover two sidewalls of the active region 901A, respectively. FIG. 9D(a) is a top view illustrating the processing structure after the SiOCN material 910 is formed; FIG. 9D(b) is a cross-sectional view taken along Y-cut as shown in FIG. 9D(a), and FIG. 9D(c) is a cross-sectional view taken along X-cut as shown in FIG. 9D(a).

Afterward, the SOD material 906 is removed, TiN layer 911 and Tungsten layer 912 are deposited between the oxide spacer 905 and SiOCN spacer 910, and then the TiN layer 911 and the Tungsten layer 912 are etched back to form the underground interconnection lines. Then, SiN layer 913 and HDP (high density plasma) oxide layer 914 are formed to cover the underground interconnection lines. FIG. 9E(a) is a top view of the processing structure after the SiN layer 307 and the HDP oxide layer 914 are formed, FIG. 9E(b) is a cross section view taken along Y-cut as shown in FIG. 9E(a), and FIG. 9E(c) is a cross section view taken along X-cut shown in FIG. 9E(a). Then the underground interconnection lines embedded and bounded by the composite STI region which at least includes STI region 904 and HDP (high density plasma) oxide layer 914 are formed. The UGI could be part of the composite STI region.

In some embodiments of the present disclosure, the UIG will be applied in access transistors of a 6T SRAM cell structure. For example, FIG. 9F is a 3D perspective view illustrating a circuit structure 900 (with a structure similar to that of the NMOS transistor 700 as depicted in FIG. 7(e)) which is applied in a 6T SRAM cell and has a UGI 913 embedded and bounded by all insulators and electrically connected to a drain region 915 (or source 925) through a self-aligned vertical connector 916. The sidewall of the vertical connector 916 is connected to the sidewall of the UGI 913. By using such the UGI electrically connecting the drain and/or source of the access transistor, the size of 6T SRAM cell structure can be thus scaled down.

Moreover, this UGI could be used for heat dissipation purpose as well in the event the UGI is not utilized for signal/power distribution. Especially, since the STI region 904 or the composite STI region not only surrounds the transistor, but also extends to the edge portion of the chip, thus, the UGI embedded in the composite STI region could also surrounds the transistor and extends to the edge portion of the chip. Therefore the heat generated from the transistor could be dissipated by the UGI to the edge of the chip which is then coupled to a heat sink. In this case, the material of UGI could be metal, SiC, poly silicon, AlN, BN, or other material with thermal conductivity higher than that of SiO₂ or Si.

### Embodiment 5 (4CFETs)

The present embodiment discloses a vertical thin body field-effect transistor (VTBFET) having lower standby current, lower gate-induced drain leakage (GIDL) current and lower short channel effect (SCE), and form a solid fence wall to clamp an active region or a narrow convex structure of the VTBFET. The VTBFET can be used in a SRAM cell structure, especially used in a 6T SRAM cell structure.

The manufacturing method of the VTBFET (using an NMOS transistor for illustration purpose) 1000 includes steps as follows: A pad-oxide layer 1002 and a pad-nitride layer 1004 are formed in sequence over an original or horizontal semiconductor surface (HSS) of the p-type well of a p-type semiconductor substrate 1001. Portions of the pad-oxide layer 1002, the pad-nitride layer 1004 and the semiconductor substrate 1001 are removed by an anisotropic etching technique to define an active region 1001A (e.g. a fin structure) of the VTBFET 1000.

An oxide spacer 1003 and a nitride spacer 1005 are deposited on the edge of the active region 1001A, and the oxide spacer 1003 and the nitride spacer 1005 are etched back by using the anisotropic etching technique to form a solid fence wall to clamp the active region 1001A to protect the fin structure from collapse during the forming the source/drain or the gate of the VTBFET.

Next, a thick oxide layer is deposited to fully fill the trench surrounding the active region 1001A and use the CMP technique to remove the excess oxide layer to form the STI region 1006, wherein a top surface of the STI region 1006 is in level up to a top surface of the pad-nitride layer 1004. Again, the STI region 1006 further encompass or clamp the active region 1001A or the narrow convex structure, especially the sidewalls of the convex structure, to protect the narrow convex structure from collapse during the forming the source/the drain or the gate of the VTBFET.

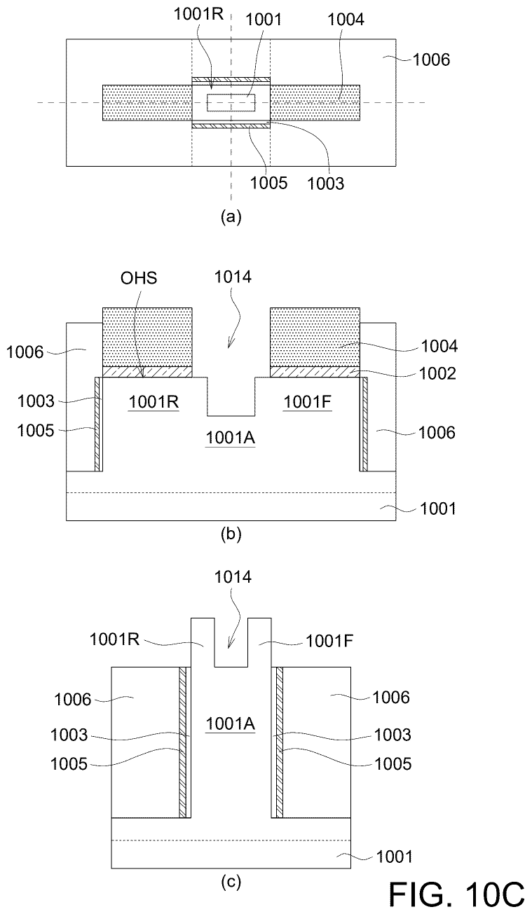

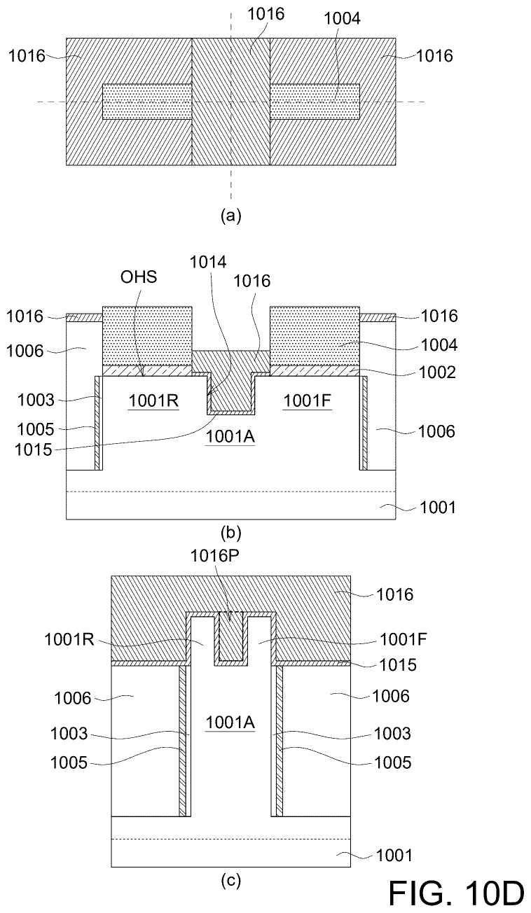

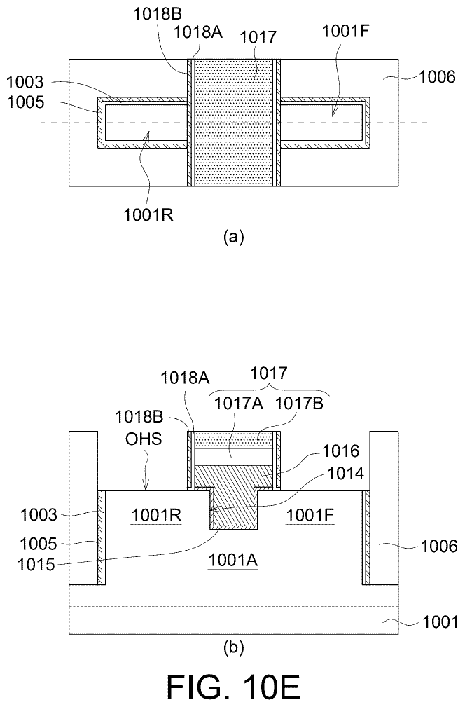

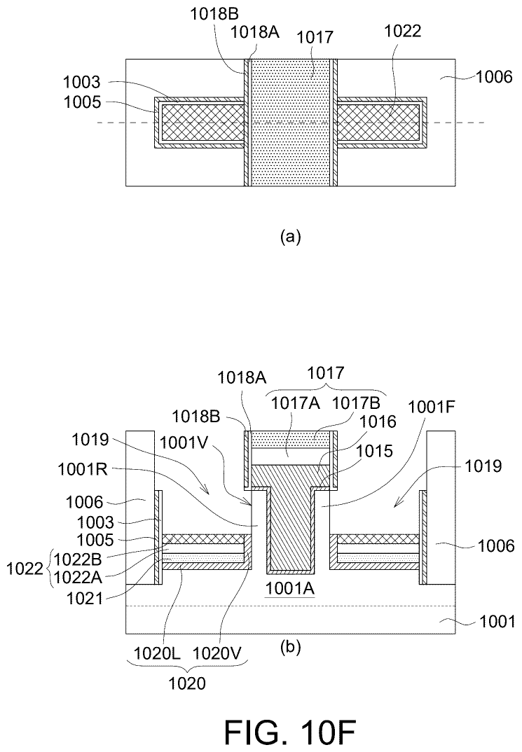

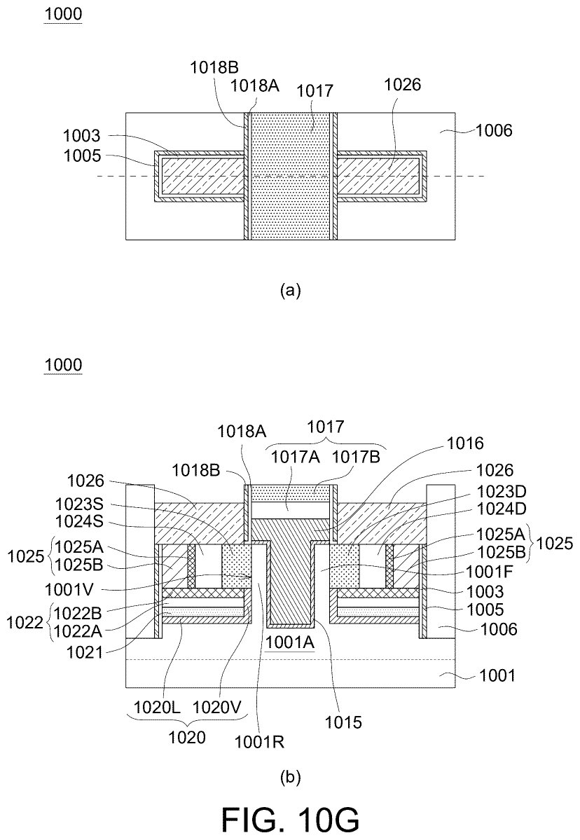

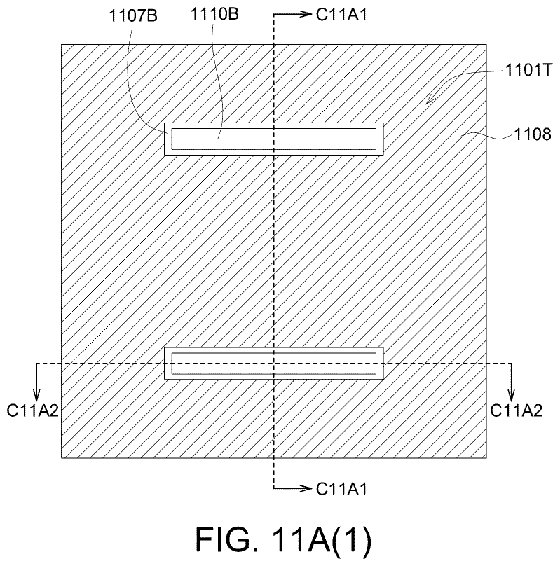

A thin nitride layer 1007 is deposited over the pad-nitride layer 1004 and the STI region 1006, a patterned the photolithographic (PR) mask 1008 used to define a gate region is deposited over the thin nitride layer 1007, and a concave 1009 is formed by removing the portions of the thin nitride layer 1007 and the pad-nitride layer 1004 corresponding to the gate region. See FIG. 10A, wherein FIG. 10A(a) is a top view illustrating the structure after the concave 1009 is formed. FIG. 10A(b) is a cross-sectional view of the structure as depicted in FIG. 10A(a) taken along the X direction. FIG. 10A(c) is a cross-sectional view of the structure as depicted in FIG. 10A(a) taken along the Y direction.

After the photolithographic (PR) mask 1008 is removed, smooth edges along the thin nitride layer 1007 and the pad-nitride layer 1004 to define the gate region of the VTBFET is achieved, and a central pole related area is also defined within the active region 1001A. A SiCOH layer (or a combination of oxide/nitride layer) is then deposited within the central pole related area and is etched back to form the SiCOH spacer 1010 on four surrounding edges inside the central pole related area to protects the original silicon regions underneath, which becomes a surrounding ring of silicon (or surrounding Si ring) on the future created central pole, named as SRS-CP.

A concave (or trench) 1011 is formed in the active region 1001A by removing the portions of the pad-oxide layer 1002 and the semiconductor material of the active region 1001A corresponding to the central pole related area to exposed silicon region, using the SiCOH spacer 1010 and the thin nitride layer 1007 acts as the etching mask. A dielectric layer is deposited to fill the concave 1011 and form a central pole 1012, or called as central oxide pole or column pole (CP). A nitride layer 1013 is then deposited and etch back to form a nitride cap 1013 over the central pole 1012. See FIG. 10B, wherein FIG. 10B(a) is a top view illustrating the structure after the nitride cap 1013 is formed. FIG. 10B(b) is a cross-sectional view of the structure as depicted in FIG. 10B(a) taken along the X direction. FIG. 10B(c) is a cross-sectional view of the structure as depicted in FIG. 10B(a) taken along the Y direction.

The exposed STI region 1006 in the defined gate region is etch back to create the convex semiconductor structure in the defined gate region, and in one example the convex height is the same or substantially the same as a height of the central pole 1012 calculated from the original horizontal surface (OHS) of the active region 1001A to a bottom of the central pole 1013 (see FIG. 10C(c)). The nitride cap 1013 and the SiCOH spacer 1010 close to the central pole related area, the thin nitride layer 1007, and the nitride spacer 1005 covering the convex structure (the active region 1001A) in the defined gate region are etched. Thus, the previously defined central pole related area is shown again. Next, the pad-oxide layer 1002 close to the central pole related area and the oxide spacer 1003 covering the convex structure are etched by another etching process. The STI region 1006 outside the gate region could be also etched down by a certain amount and the top surface of the STI region 1006 is lower than the top surface of the pad-nitride layer 1004.

Thus, two outer sides of single crystalline silicon of the convex structure (the active region 1001A) are exposed. There is a surrounding ring of silicon on the central pole (SRS-CP) 1011. Thereafter, the central pole 1011 is removed and a trench 1014 is revealed. In the convex structure (the active region 1001A), there are two vertical thin (silicon) bodies 1001R and 1001F for current conduction during the ON state of the VTBFET 1000. There is on STI region between the vertical thin (silicon) bodies. The vertical thin body 1001R has one outer sidewall and one inner sidewall next to the trench 1014, so does the vertical thin body 1001F. The inner sidewall of the vertical thin body 1001R faces the inner sidewall of the vertical thin body 1001F in the trench 1014. See FIG. 10C, wherein FIG. 10C(a) is a top view illustrating the structure after the STI region 1006 is etched down. FIG. 10C(b) is a cross-sectional view of the structure as depicted in FIG. 10C(a) taken along the X direction. FIG. 10C(c) is a cross-sectional view of the structure as depicted in FIG. 10C(a) taken along the Y direction.

Then a gate dielectric (such as high K dielectric materials or oxide) 1015 is formed in the gate region. A conductive material 1016 (such as polysilicon, or metal like tungsten over TiN layer, or other metal with suitable work function) is deposited in the gate region, and portions of the gate conductive material is then removed by using etch back process. The portion of the gate conductive material remained in the trench 1014 could be called “conductive central pole” 1016P, and the conductive central pole 1016P is surrounded by the gate dielectric 1015 in the trench 1014. See FIG. 10D, wherein FIG. 10D(a) is a top view illustrating the structure after the conductive central pole 1016P is formed. FIG. 10D(b) is a cross-sectional view of the structure as depicted in FIG. 10D(a) taken along the X direction. FIG. 10D(c) is a cross-sectional view of the structure as depicted in FIG. 10D(a) taken along the Y direction.

A cap layer 1017 which could be composed of a nitride layer 1017A and a hard-mask-oxide layer 1017B is formed on a top surface of the gate material 1016 corresponding to the gate region. Then, the pad-nitride layer 1004 and the pad-oxide layer 1002 are etched away to reveal the OHS of the (the active region 1001A). And then an oxide spacer 1018A and a nitride spacer 1018B are formed on the edges of the gate material 1016 and the cap layer 1017. See FIG. 10E, wherein FIG. 10E(a) is a top view illustrating the structure after the oxide spacer 1018A and a nitride spacer 1018B are formed. FIG. 10E(b) is a cross-sectional view of the structure as depicted in FIG. 10E(a) taken along the X direction.

Some exposed silicon areas of the in the active region 1001A are then etched away to create shallow trenches 1019 for the source region and the drain region of the VTBFET 1000. An oxide layer 1020 (including both an oxide layers 1020V penetrating vertical sidewalls of the shallow trenches 1019 defined by the bulk body of the VTBFET 1000 (assuming with a sharp crystalline orientation (110)), and an oxide layer 1020L over the bottom of the shallow trenches 1019) are grown using a thermal oxidation process. Based on the oxidation process, the thickness of oxide layer 1020 can be very accurately controlled under both precisely controlled thermal oxidation temperature, timing and growth rate. In one embodiment, the edge of the oxide layer 1020V could be aligned or substantially aligned with the edge of the gate structure.

A nitride layer 1021 is formed on a top surface of the oxide-3B layer 1020 by CVD. A metal layer 1022 including a tungsten layer 1022A and a TiN layer 1022B is then deposited on a top surface of the nitride layer 1021. Then portions of the oxide layer 1020V are etched away using a top surface of the TiN layer 1022B as reference to reveal silicon sidewalls 1001V (with the crystalline orientation (110)) of the active region 1001A from the shallow trenches 1019. In another example, the steps to form the tungsten layer 1022A and the TiN layer 1022B could be omitted, and etching the portion of the oxide layer 1020V could use the top surface of the nitride layer 1021 as reference. See FIG. 10F, wherein FIG. FIG. 10F(a) is a top view illustrating the structure after the portions of the oxide layer 1020V are etched away to reveal the silicon sidewalls 1001V. FIG. 10F(b) is a cross-sectional view of the structure as depicted in FIG. 10F(a) taken along the X direction.

The lightly doped (such as n− for NMOS) LDDs 1023S and 1023D are formed based on the exposed silicon sidewalls 1001V by using a selective growth (SEG) technique, and heavily doped (such as n+ for NMOS) source 1024S and heavily doped drain 1024B are then formed by another SEG technique based on the lateral sidewalls of LDDs 1023S and 1023D. To be mentioned, no ion-implantations for forming all n-type LDDs 1023S and 1023D, the n+ doped source 1024S and the n+ doped drain 1024D of the VTBFET 1000 are needed and no high temperature thermal annealing is necessary to remove those damages due to heavy bombardments of forming the n+ doped source 1024S and the n+ doped drain 1024D.

Finally, deposit a TiN layer 1025A and a tungsten layer 1025B, and the TiN layer 1025A and the tungsten layer 1025B are then etched back to form metal contacts 1025 for the n+ doped source 1024S and the n+ doped drain 1024D. Landing pads 1026 are formed over the metal contacts 1025, so the contact resistance is reduced accordingly. Since the STI region 1006 is higher than the horizontal semiconductor surface HSS, the TIN layer 1025A and a tungsten layer 1025B will be confined between the gate structure and the STI region 1006 (so is the landing pads 1026) without using other photomask to define the contact holes for the source/drain regions. Thus, a self-aligned process is accomplished. Moreover, in another embodiment, the metal contacts 1025 and the landing pads 1026 could be formed simultaneously. See FIG. 10G, wherein FIG. 10G(a) is a top view of the VTBFET 1000. FIG. 10G(b) is a cross-sectional view of the VTBFET 1000 taken along the X direction as depicted in FIG. 10G(a).

The conductive central pole 1016P exists between the vertical thin bodies 1001R and 1001F of the active region 1001A (e.g. a fin structure). With suitable gate metal material to adjust the work function of the conductive central pole 1016P and/or the gate conductive material, the current density during the ON-state of the VTBFET 1000 could be 7 times of that of the conventional FinFET (not shown), and Ion of the present invention is around 2 times of that of the conventional FinFET. It is noticed that, due to the vertical thin bodies 1001R and 1001F, there are multiple current conductive channels in the new vertical thin body field-effect transistor (i.e. the VTBFET 1000). On the other hand, the current density during the Off-state of the conventional FinFET is 17 times of that of the VTBFET 1000, and Ioff of the conventional FinFET transistor is 34 times of that of the VTBFET 1000. Thus, the present VTBFET 1000 effectively improves the Ion/Ioff ratio about 68 times, as compared with the convention FinFET.

### Embodiment 6 (New Poly-Cut Processes)

This embodiment discloses a new poly cut process for transistor structure 1100 having two MOS transistors T111 and T112, respectively formed based on two adjacent fin (or GAA) structures 1101F1 and 1101F2, especially used in a 6T SRAM cell structure. The manufacturing method of the transistor structure 1100 is exemplarily illustrated as follows:

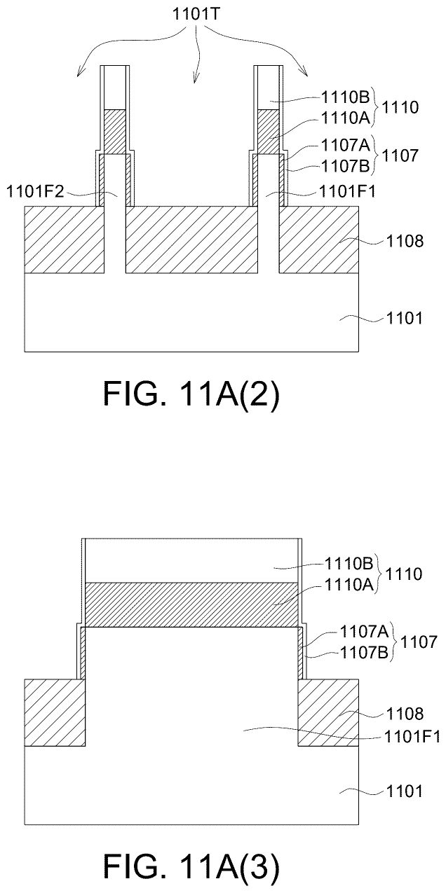

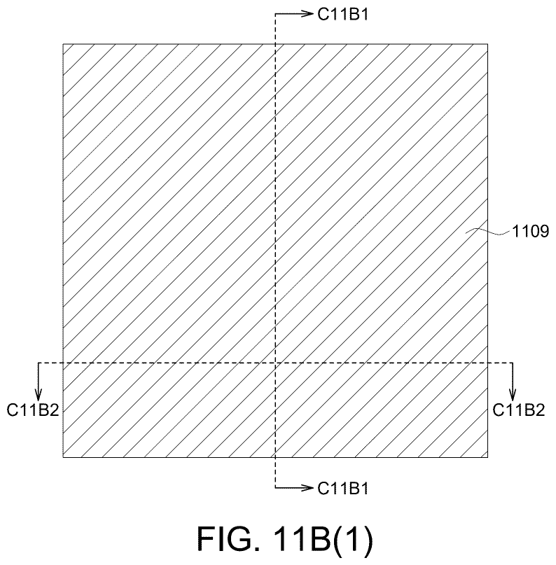

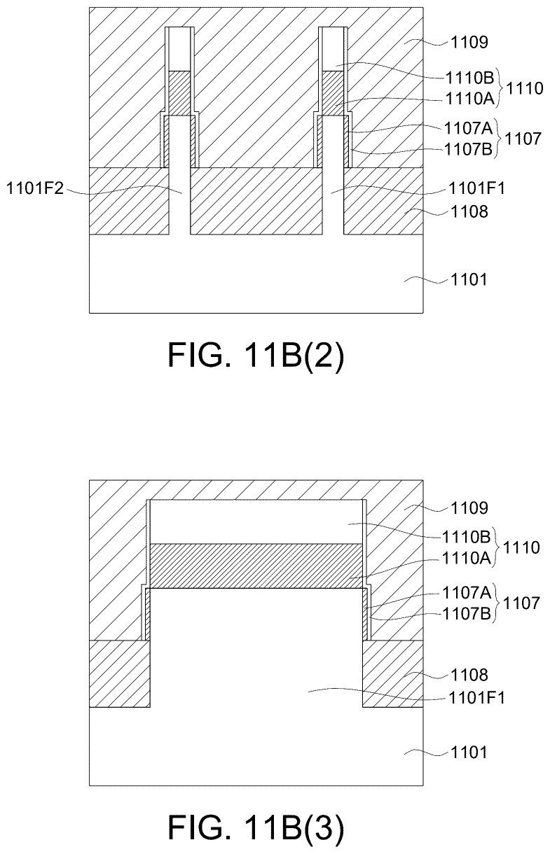

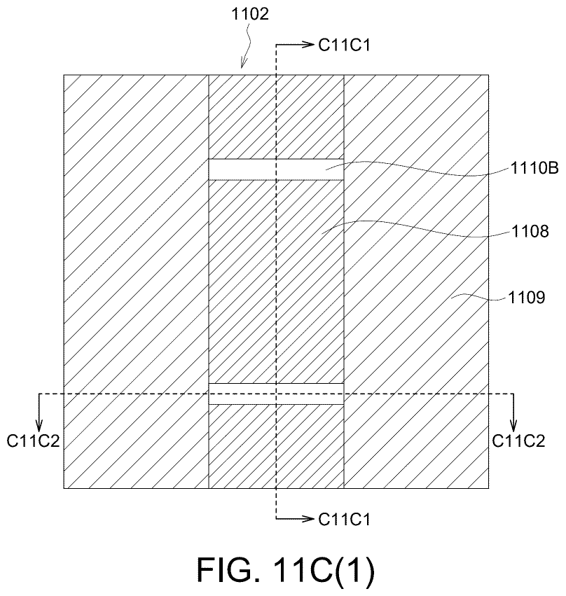

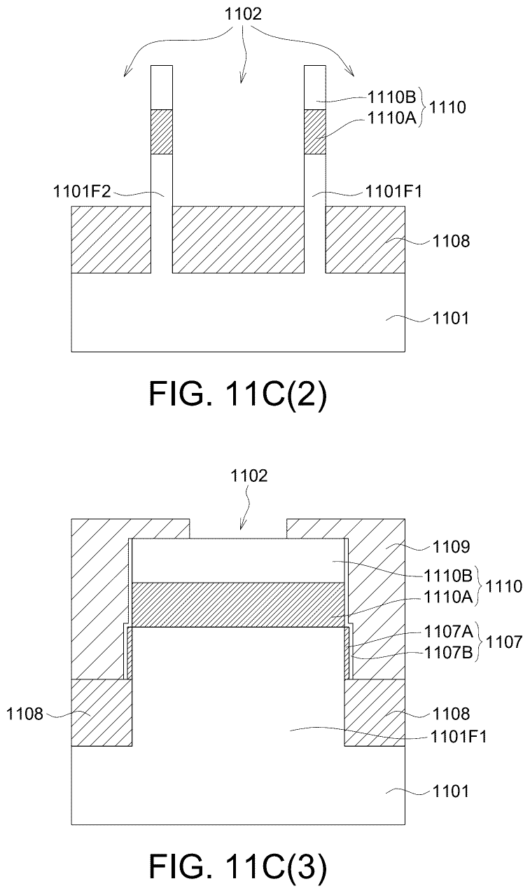

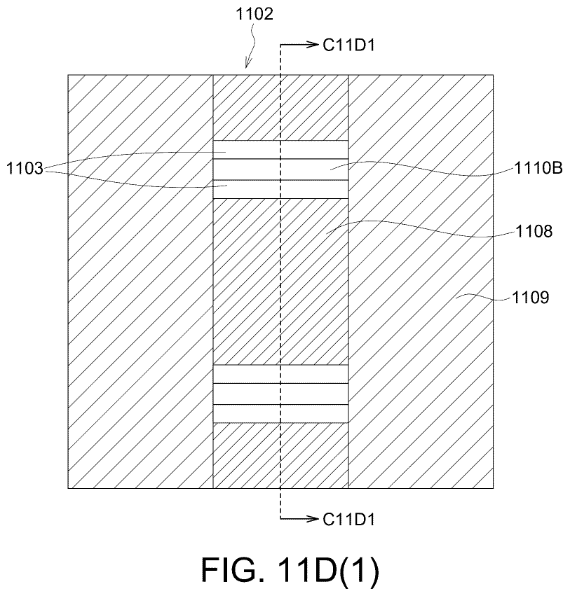

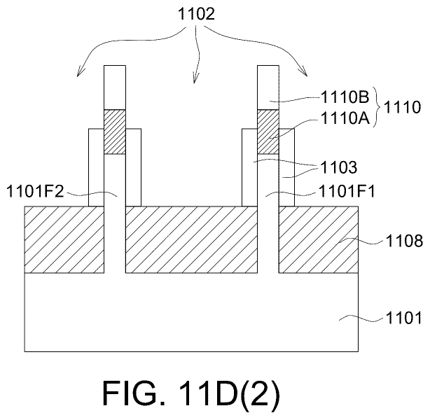

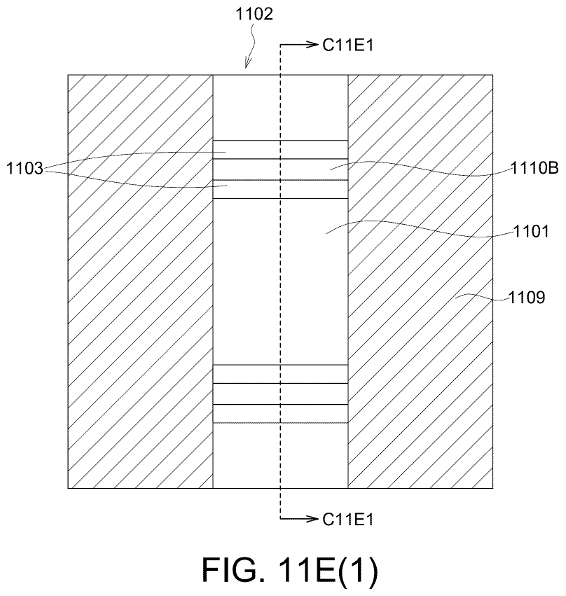

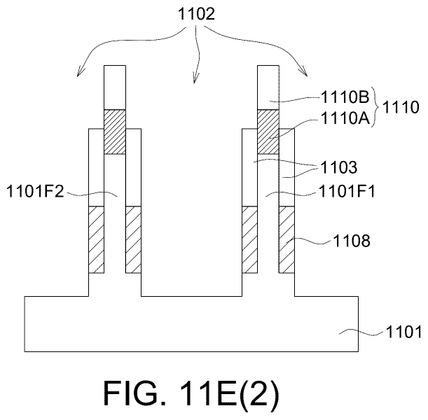

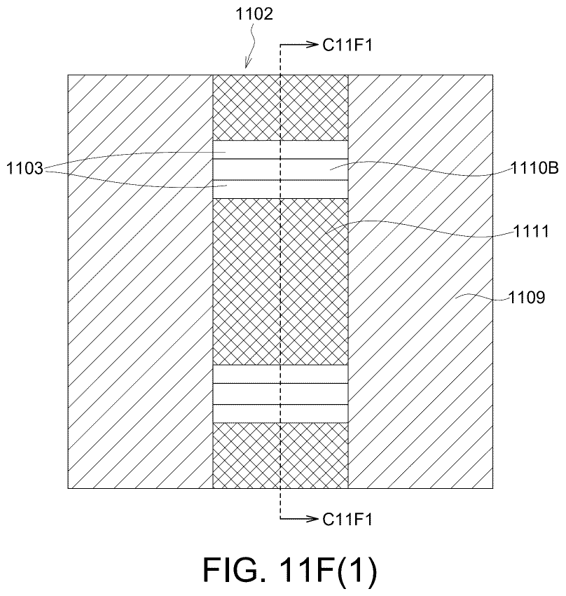

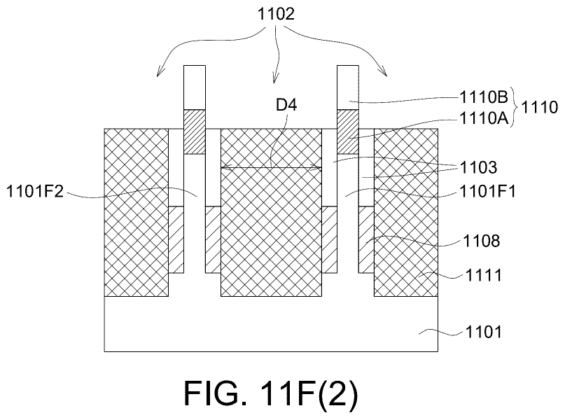

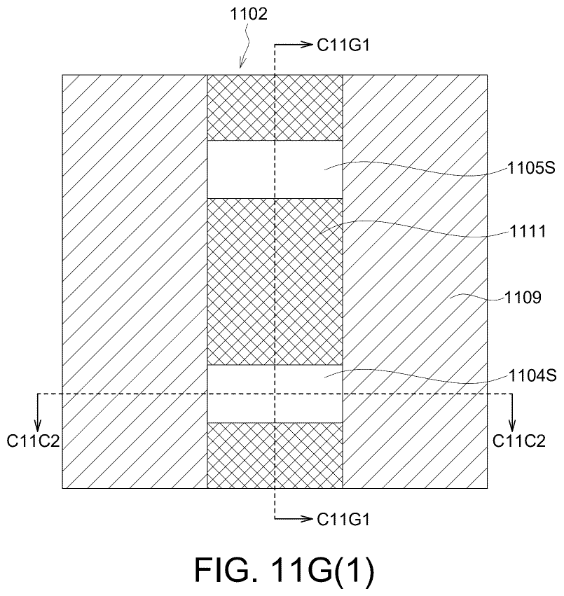

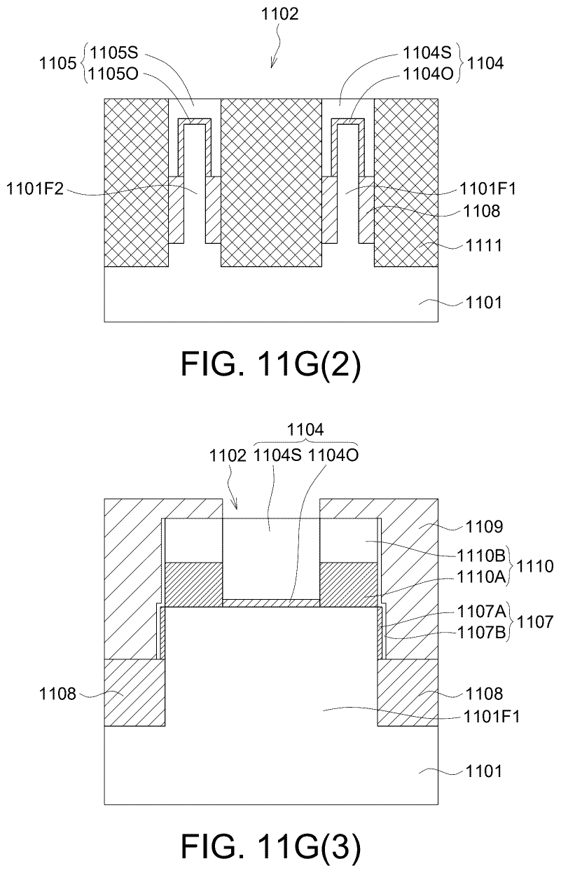

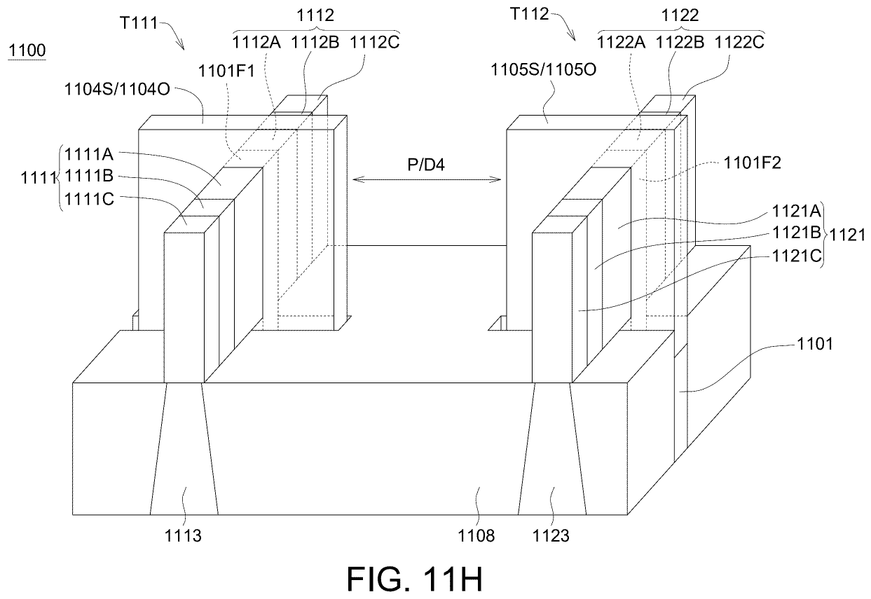

A plurality of fin structures 1101F1 and 1101F2 are defined in a semiconductor substrate 1101, each of the fin structures 1101F1 and 1101F2 is surrounded by a fin spacer 1107. Referring to FIGS. 11A(1) to 11A(3), FIG. 11A(1) is a top view illustrating the structure after the fin structures 1101F1 and 1101F2 are defined in the semiconductor substrate 1101; FIG. 11A(2) is a cross-sectional view taken along the cutting line C11A1 as depicted in FIG. 11A(1); and FIG. 11A(3) is a cross-sectional view taken along the cutting line C11A2 as depicted in FIG. 11A(1). The fin structures 1101F1 and 1101F2 are defined by Sub-Steps S711-S715 as follows:

An etching process using a patterned pad dielectric layer 1110 (including a patterned pad oxide layer 1110A and a patterned pad nitride layer 1110B) as an etching mask is performed to remove parts of silicon material of a semiconductor substrate 1101 to create trenches 1101T and define a plurality of fin structures 1101F1 and 1101F2 in the semiconductor substrate 1101. In some embodiments, the distance of the adjacent two fin structures 1101F1 and 1101F2 may be about 30-50 nm. Each of the fin structures 1101F1 and 1101F2 has a thickness about 3-10 nm, such as 5 nm.

A shallow trench isolation (STI) regions 1108 is formed surrounding the fin structures 1101F1 and 1101F2. In some embodiments of the present disclosure, oxide material is deposited to fully fill the trenches 1101T and then etched back, such that the oxide material remained in the trenches 1101T can serve as STI regions 1108 surrounding the plurality of fin structures 1101F1 and 1101F2. An etching back process is performed to remove portions of the shallow trench isolation (STI) regions 1108, so as to expose sidewalls of the fin structures 1101F1 and 1101F2.

Next, a thermal oxidation process is performed to form the oxide spacers 1107A on the sidewalls of the fin structures 1101F1 and 1101F2; and a nitride deposition process is performed to form the nitride spacers 1107B on the oxide spacers 1107A (as shown in FIGS. 7A(2) and 7A(3)).

Thereafter, gate openings 1102 are defined in a capping dielectric layer 1109 covering the fin structures 1101F1 and 1101F2 and the STI regions 1108, wherein the sidewalls of each of the fin structures 1101F1 and 1101F2 are partially exposed from corresponding one of the gate openings 1102. First, an oxide deposition process is performed to form the capping dielectric layer 1109 on the fin structures 1101F1 and 1101F2. See FIGS. 11B(1) to 11B(3), FIG. 11B(1) is a top view illustrating the structure after the capping dielectric layer 1109 is formed to cover the fin structures 1101F1 and 1101F2; FIG. 11B(2) is a cross-sectional view taken along the cutting line C11B1 as depicted in FIG. 11B(1); and FIG. 11B(3) is a cross-sectional view taken along the cutting line C11B2 as depicted in FIG. 11B(1). In the present embodiment, the oxide deposition process for forming the capping dielectric layer 1109 is followed by a planarization process; and the capping dielectric layer 1109 includes SiO₂.

Then, patterned process is performed to remove a portion of the capping dielectric layer 1109 to define the gate opening 1102, from which the nitride spacers 1107B are exposed. Afterward, the nitride spacers 1107B and the oxide spacers 1107A are then removed respectively by another etching process, so as to make each of the fin structures 1101F1 and 1101F2 partially exposed from the gate opening 1102. See FIGS. 11C(1) to 11C(3), FIG. 11C(1) is a top view illustrating the structure after the fin structures 1101F1 and 1101F2 are partially exposed from the gate opening 1102; FIG. 11C(2) is a cross-sectional view taken along the cutting line C11C1 as depicted in FIG. 11C(1); and FIG. 11C(3) is a cross-sectional view taken along the cutting line C11B2 as depicted in FIG. 11C(1).

Epitaxial semiconductor material 1103 (serving as a sacrificial spacer) are formed based on the exposed portions of the fin structures 1101F1 and 1101F2. See FIGS. 11D(1) and 11D(2), wherein FIG. 11D(1) is a top view illustrating the structure after the epitaxial semiconductor material 1103 is formed; and FIG. 11D(2) is a cross-sectional view taken along the cutting line C11D1 as depicted in FIG. 11D(1). In some embodiments of the present disclosure, the epitaxial semiconductor material 1103 (such as Si, SiGe, Ge, etc.) is formed by a SEG method based on the exposed portions of the fin structures 1101F1 and 1101F2. In some other embodiments of the present disclosure, other semiconductor epitaxial material (such as, GaAs, GaN, SiC, etc.) may be grown based on the exposed portions of the fin structures 1101F1 and 1101F2. The epitaxial semiconductor material 1103 has a thickness about 5˜12 nm, such as 7-8 nm.

Next, the gate openings 1102 are deepen to expose the semiconductor substrate 1101. See FIGS. 11E(1) and 11E(2). FIG. 11E(1) is a top view illustrating the structure after the gate openings 1102 are deepen to expose the semiconductor substrate 1101; and FIG. 11E(2) is a cross-sectional view taken along the cutting line C4E1 as depicted in FIG. 11E(1). In some embodiments of the present disclosure, an etching process is performed to remove the portion of the STI regions 1108 exposed from the gate opening 1102 and the portion of the semiconductor substrate 1101 beneath the removed portion of the STI regions 1108.

Thereafter, the gate openings 1102 are filed by an inserting dielectric layer 1111 to surround the epitaxial semiconductor material 1103 and the remained STI regions 1108. See FIGS. 11F(1) and 11F(2). FIG. 11F(1) is a top view illustrating the structure after the gate opening 1102 is filed by an inserting dielectric layer 1111; and FIG. 11F(2) is a cross-sectional view taken along the cutting line C11F1 as depicted in FIG. 11F(1). In some embodiments of the present disclosure, the material constituting the inserting dielectric layer 1111 may be different from that constituting the capping dielectric layer 1109. In the present embodiment, the inserting dielectric layer 1111 is formed by a low-k dielectric material (such as, SiCOH) deposition process. The bottom of the inserting dielectric layer 1111 (SiCOH) is lower than the bottom of the STIs 1108. Since the dielectric constant of the inserting dielectric layer 1111 (SiCOH) is lower than that of the STI regions 1108, therefore, the coupling effect between two gate structures 1104 and 1106 (which will be formed later, see FIGS. 11G(1) to 11G(3)) could be improved. The inserting dielectric layer 1111 may be then etched back. Such that, the patterned pad nitride layer 1110B can be exposed from the partially filled gate opening 1102. Moreover, as shown in FIG. 11F(2), the distance D4 between two epitaxial semiconductor material 1103 (or sacrificial spacers) is around 15˜30 nm, such as 20 nm, and the distance D4 could be equal to or substantially equal to the “gate cut” or “poly cut” distance between two gate structures of the adjacent transistors.

Then, the epitaxial semiconductor material 1103 is removed to form vacancies; and the nitride spacers 1107B and the oxide spacers 407A are removed to expose the fin structures 1101F1 and 1101F2. Afterward, the G=gate structures 1104 and 1105 are formed respectively on the fin structures 1101F1 and 1101F2. See FIGS. 11G(1) to 11G(3). FIG. 11G(1) is a top view illustrating the structure after the gate structures 1104 and 1105 are formed; FIG. 11G(2) is a cross-sectional view taken along the cutting line C11G1 as depicted in FIG. 11G(1); and FIG. 11G(3) is a cross-sectional view taken along the cutting line C11G2 as depicted in FIG. 11G(1).

To form the gate structures 1104 and 1105, the gate dielectric layers 11040 and 11050 are formed respectively covering the tops and sidewalls of the fin structures 1101F1 and 1101F2. In some embodiments of the present disclosure, the gate dielectric layers 11040 and 11050 are formed by an oxide deposition process. Then, the gate electrodes 1104S and 1105S are formed respectively covering the gate dielectric layers 11040 and 11050. In some embodiments of the present disclosure, the gate electrodes 1104S and 1105S are formed by polysilicon or metal. Thus, the vacancies formed after the epitaxial semiconductor material 1103 is removed are just be filled with the gate dielectric layers 11040 and 11050 and the gate electrodes 1104S and 1105S.

Subsequently, as described in previously embodiments, localized isolations 1113 and 1123 are formed in the semiconductor substrate 1101. A source region 1111 including an LDD region (e.g. N-semiconductor region) 1111A, a N+ semiconductor region 1111B and a landing pad 1111C, as well as a drain region 1112 including an LDD region (e.g. N-semiconductor region) 1112A, a N+ semiconductor region 1112B and a landing pad 1112C are formed over the localized isolation 1113 and electrically contact to the fin (or GAA) structure 1101F1. A source region 1121 including an LDD region (e.g. N-semiconductor region) 1121A, a N+ semiconductor region 1121B and a landing pad 1121C, as well as a drain region 1122 including an LDD region (e.g. N-semiconductor region) 1122A, a N+ semiconductor region 1122B and a landing pad 1122C are formed over the localized isolation 1123 and electrically contact to the fin (or GAA) structure 1101F2. Such that, two adjacent NMOS transistors T111 and T112 separated from each other for a certain gate electrode distance P can be formed, wherein the gate electrode distance P can be equal to the certain distance D4 that is defined by the portion of the inserting dielectric layer 1111 disposed between the two adjacent fin structures 1101F1 and 1101F2 (as shown in FIG. 11H).

Since, the certain distance D4 can be well controlled by depositing and etching back the inserting dielectric layer 1111, which is far less than the traditional lithography rule used to define the gate electrode distance P of two adjacent MOS transistors defined by lithography etching process, thus the gate electrode distance P two adjacent NMOS transistors T111 and T112 can be significant minimized. Thus, the gate electrode distance (or called “gate-cut” or “poly cut” distance) of the present invention is determined by the width of the inserting dielectric layer, rather than the lithography mask used in conventional SRAM structure.

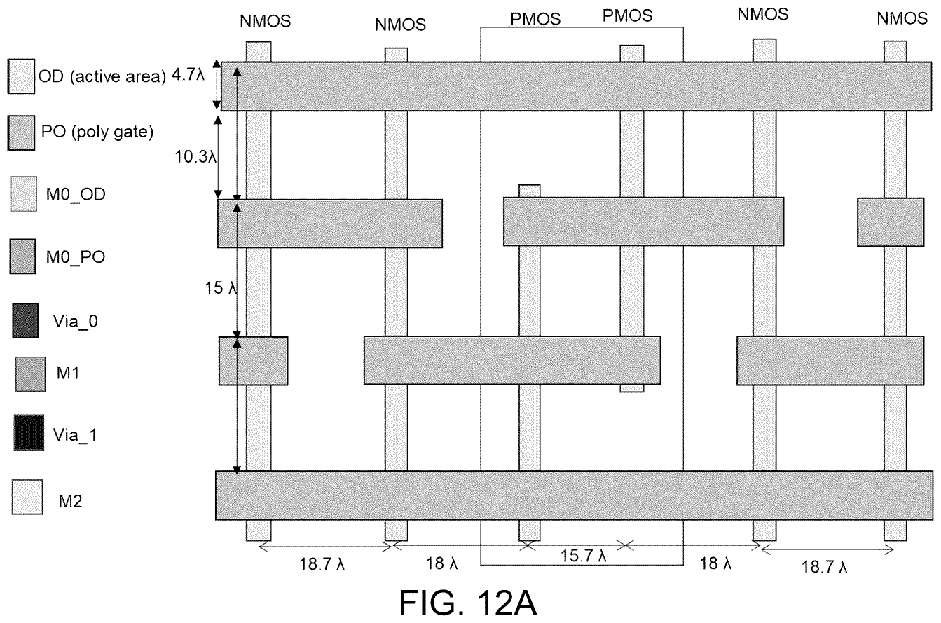

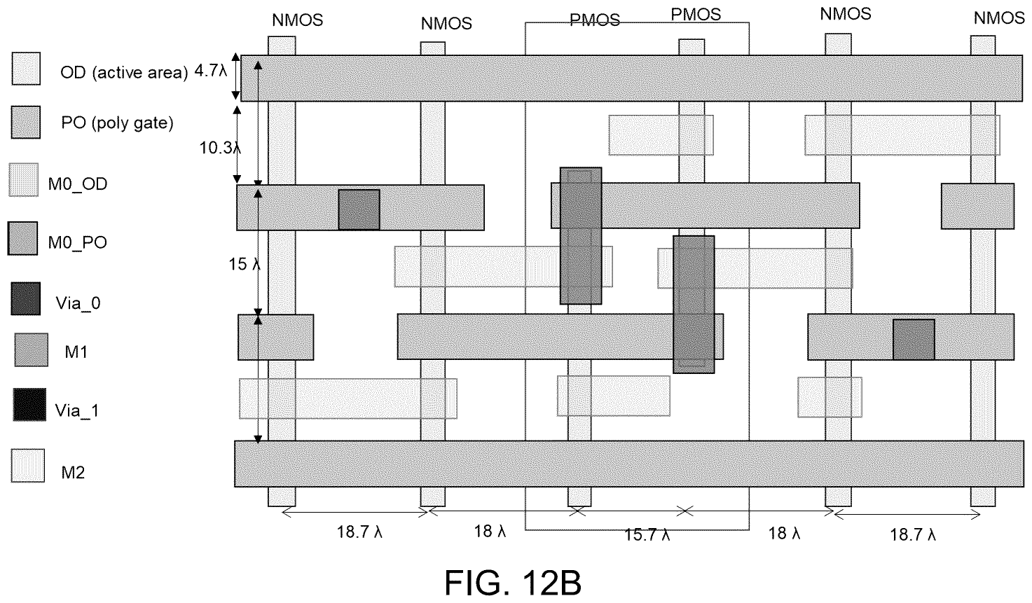

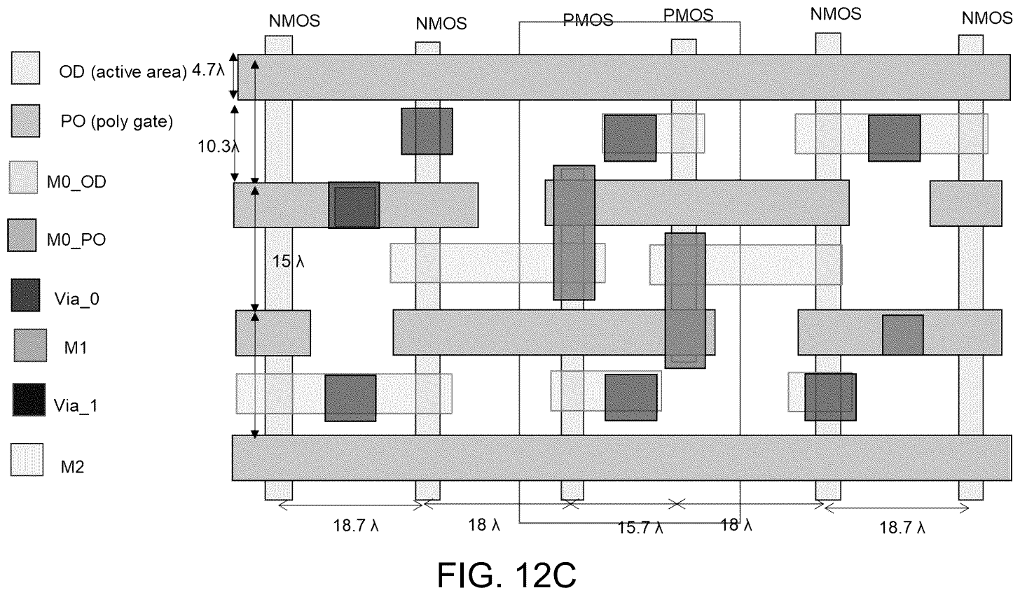

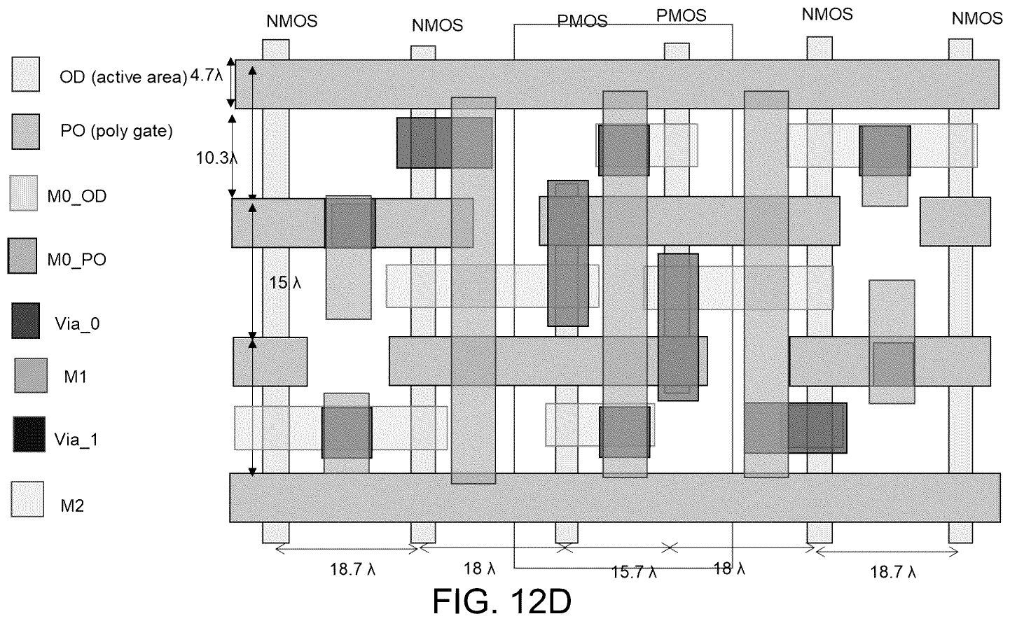

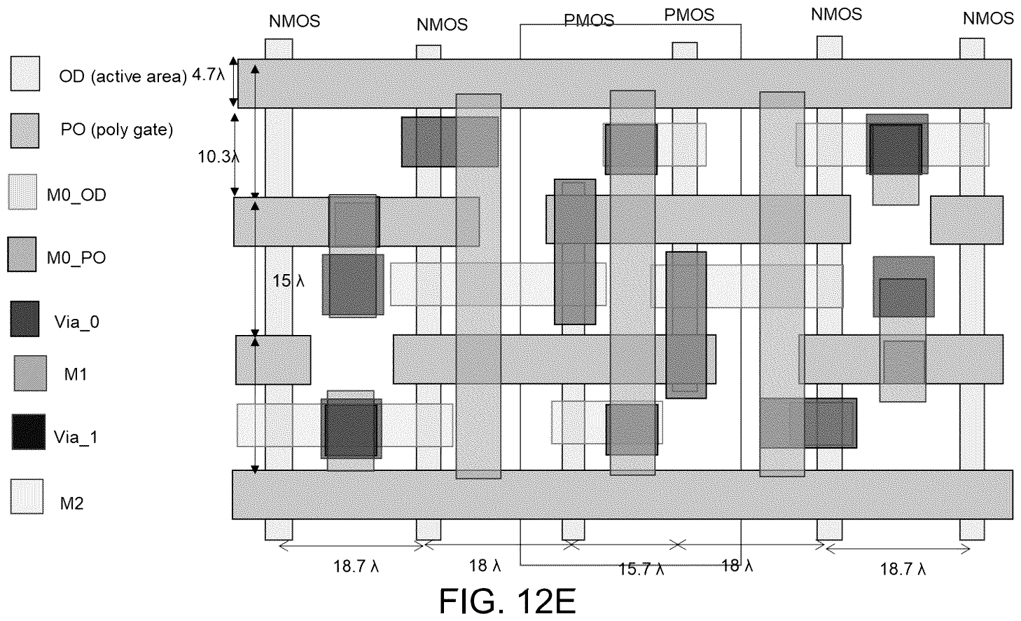

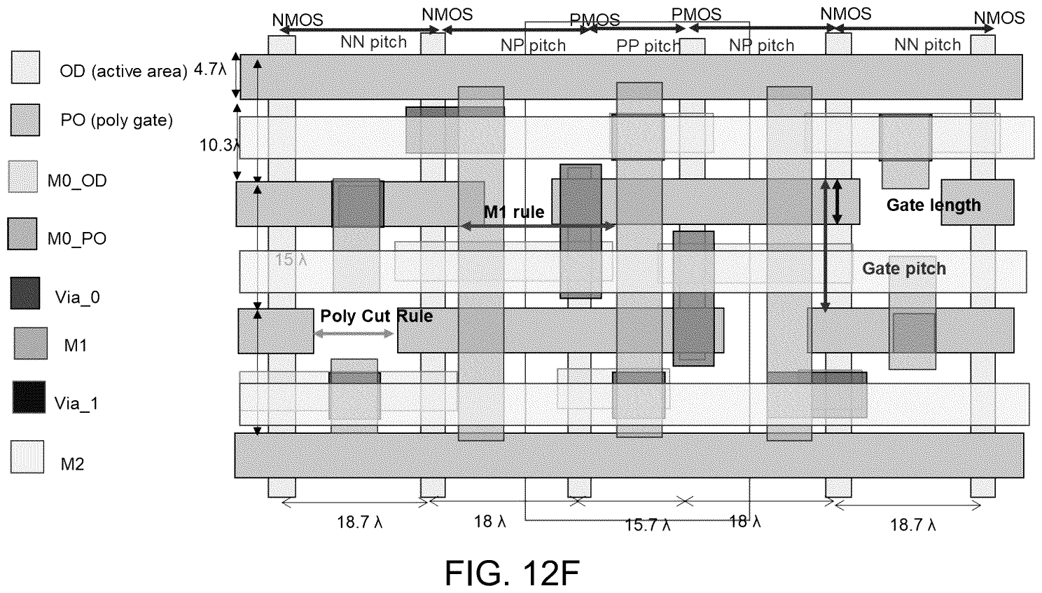

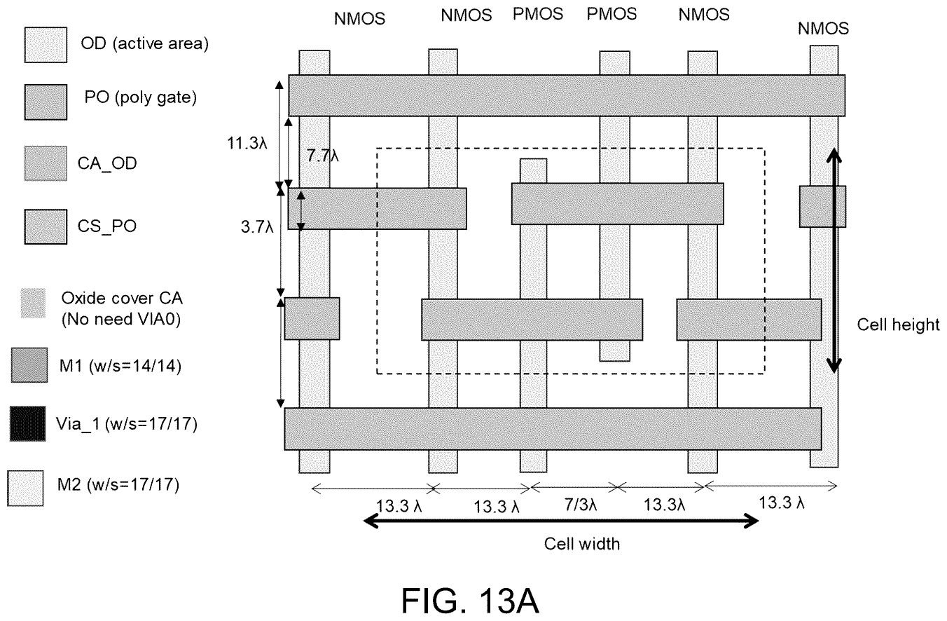

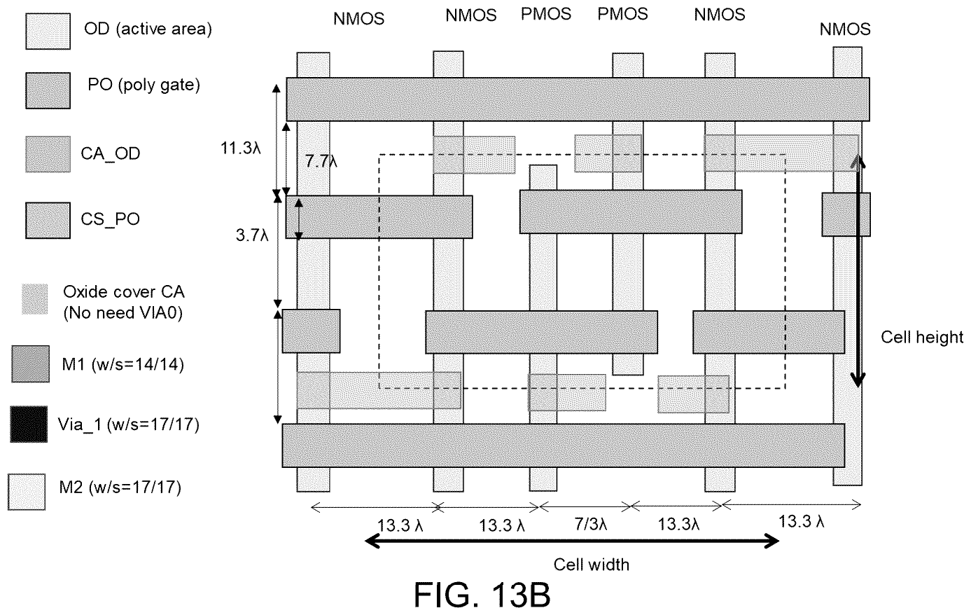

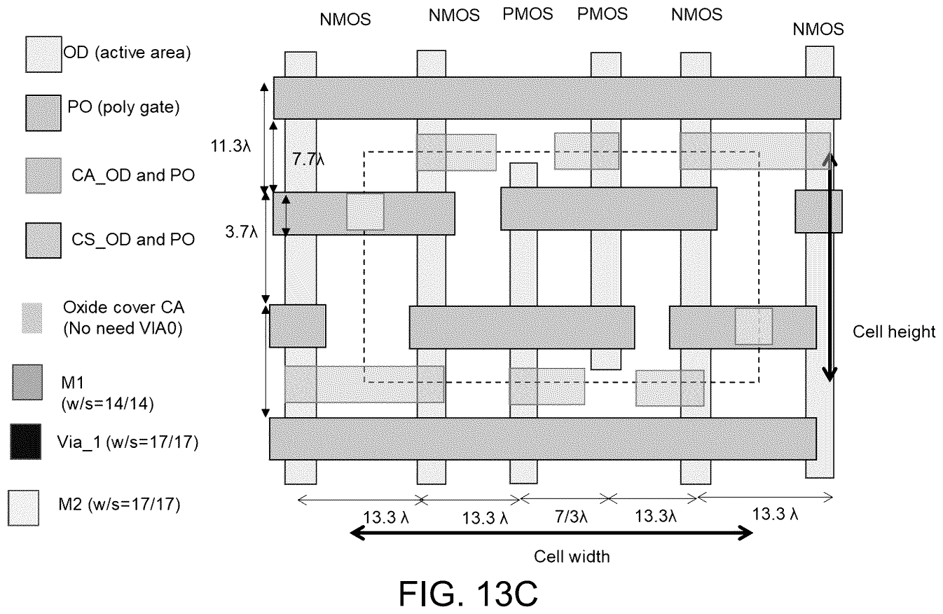

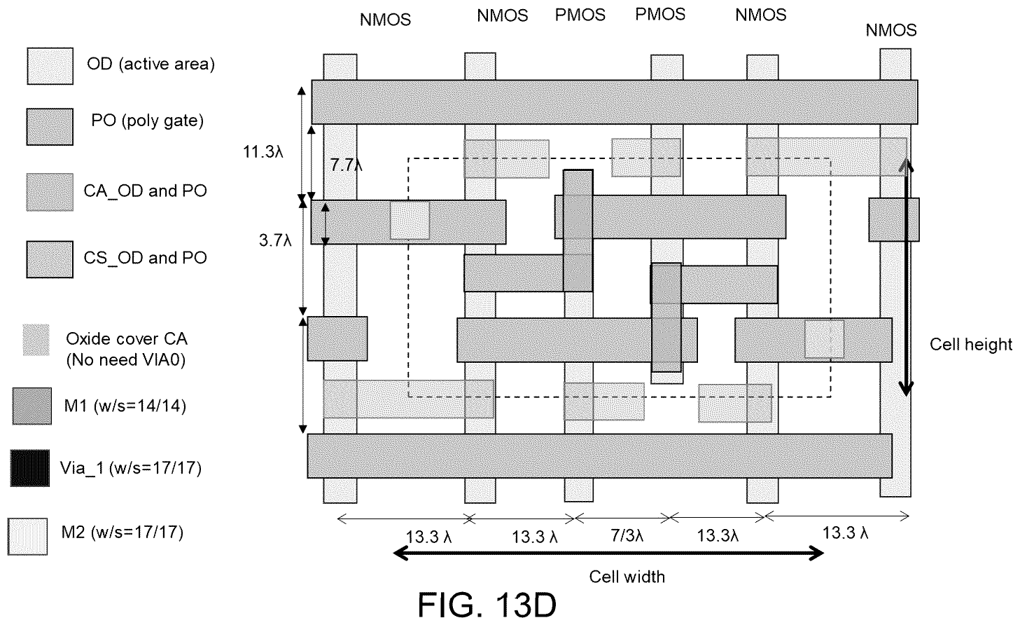

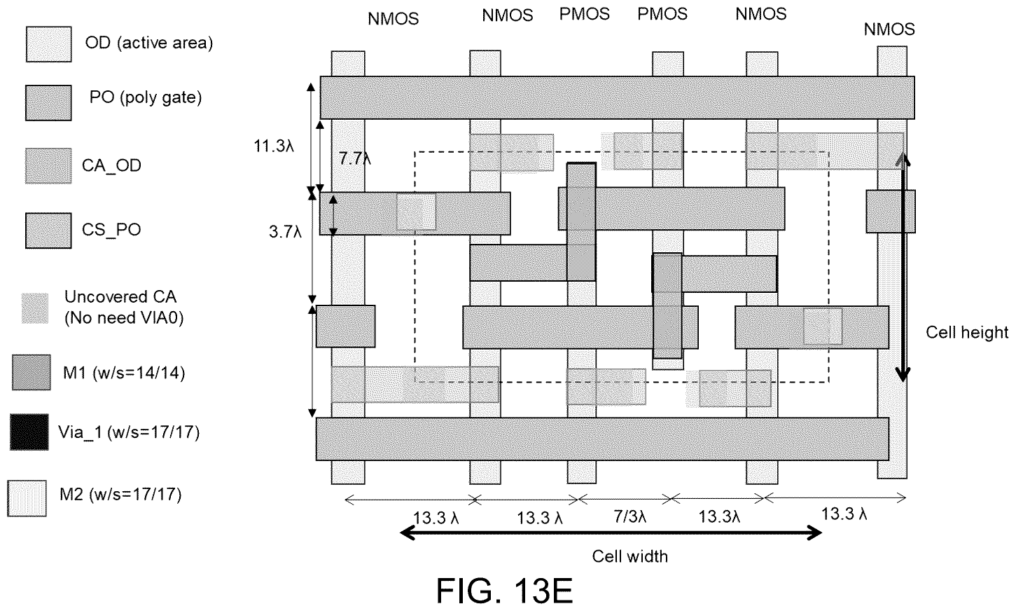

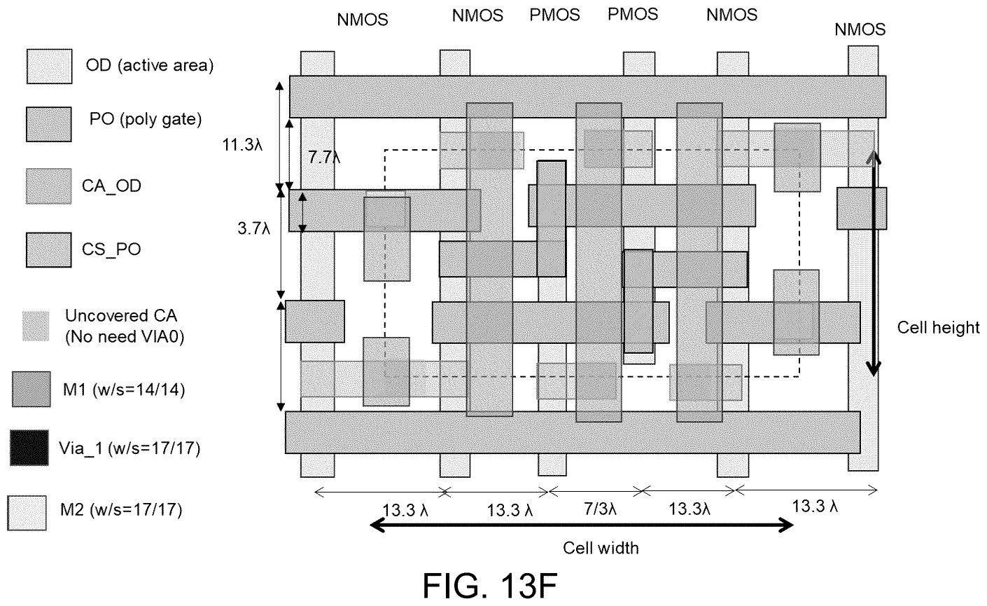

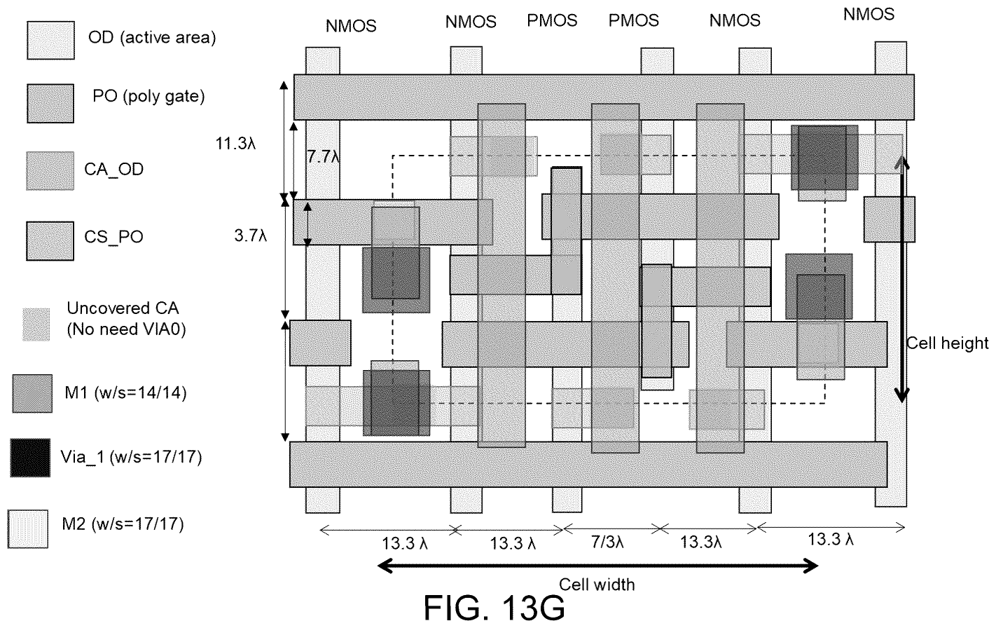

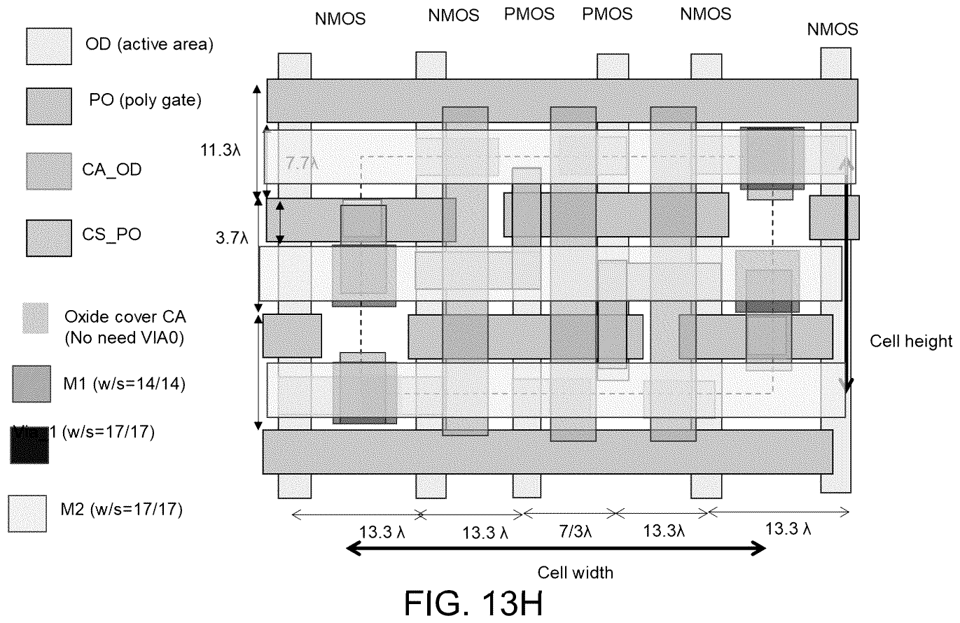

The transistors provided by the aforementioned embodiments 1-7 can be applied to form a 6T SRAM structure. For example, FIGS. 12A-12F are diagrams illustrating the processing layouts for forming a conventional 6T SRAM structure based on N3 (3 nm) technology node. FIGS. 13A-13H are diagrams illustrating the processing layouts for forming a new 6T SRAM structure based on NuCMOS structure.

However, the advantage and application of these embodiments 1-6 are not limited to this regards. The transistors and the pertinent technology provided by the aforementioned embodiments 1-6 can be either singularly or in combination applied to the forming of a new SRAM structure. Several actual SRAM formed by the transistors provided by the aforementioned embodiments and the combination thereof, as well as the examining results thereof are listed in Table 1 and Table 2 as follows, based on different technology or process nodes (λ, or called minimum feature length) from λ=16 nm (N16) to λ=3 nm (N3). Here the definition of M1 rule, poly cut rule, gate length, gate pitch, and NN/NP/PP pitch are defined in FIG. 12F. The SRAM cell area could be shown in terms of λ².

TABLE 1

| SRAM structure | | OpCMOS (Diamond shaped S/D) | | | | | NuCMOS (rectangular shaped S/D) | | | | | NuCMOS + UGI | | | | |
|---|---|---|---|---|---|---|---|---|---|---|---|---|---|---|---|---|
| FEOL rule | | N16 | N10 | N7 | N5 | N3 | N16 | N10 | N7 | N5 | N3 | N16 | N10 | N7 | N5 | N3 |
| BEOL rule | | N16 | N10 | N7 | N5 | N3 | N16 | N10 | N7 | N5 | N3 | N16 | N10 | N7 | N5 | N3 |
| M1 rule | | 64 | 47 | 40 | 28 | 23 | 64 | 47 | 40 | 28 | 23 | 64 | 47 | 40 | 28 | 23 |
| Poly cut rule | | 48 | 37 | 28 | 20 | 20 | 48 | 37 | 28 | 20 | 20 | 48 | 37 | 28 | 20 | 20 |
| Gate length (nm) | | 32 | 20 | 20 | 19 | 14 | 28 | 20 | 16 | 14 | 11 | 28 | 20 | 16 | 14 | 11 |
| Gate pitch (nm) | | 80 | 61 | 48 | 43 | 38 | 52 | 44 | 40 | 38 | 34 | 52 | 44 | 40 | 38 | 34 |
| Fin | NP | 91 | 54 | 53 | 48 | 47 | 87 | 67 | 57 | 48 | 42 | 87 | 67 | 57 | 48 | 42 |
| pitch | NN | 115 | 90 | 77 | 48 | 47 | 87 | 67 | 57 | 48 | 42 | 87 | 67 | 57 | 48 | 42 |
| (nm) | PP | 47 | 47 | 47 | 47 | 47 | 48 | 33 | 31 | 28 | 26 | 48 | 33 | 31 | 28 | 26 |

| | | | | | | | | | | | | | | | |
|---|---|---|---|---|---|---|---|---|---|---|---|---|---|---|---|
| Cell area ×10⁻² | 5.5 | 2.9 | 2.2 | 1.6 | 1.4 | 3.2 | 2.1 | 1.6 | 1.2 | 0.01 | 3.2 | 2.1 | 1.6 | 1.2 | 0.01 |
| (um²) | | | | | | | | | | | | | | | |
| Cell area (λ²) | 216 | 299 | 451 | 657 | 1588 | 126 | 209 | 320 | 496 | 1118 | 126 | 209 | 320 | 496 | 1118 |
| Cell scaling % | 20% | 17% | 12% | 24% | 25% | 56% | 49% | 43% | 42% | 47% | 56% | 49% | 43% | 42% | 47% |

TABLE 2

| SRAM | | NuCMOS + poly cut | | | | | 4CFETs in NuCMOS | | | | | 4CFETs in NuCMOS + UGI + poly cut | | | | |
|---|---|---|---|---|---|---|---|---|---|---|---|---|---|---|---|---|
| FEOL rule | | N16 | N10 | N7 | N5 | N3 | N16 | N10 | N7 | N5 | N3 | N16 | N10 | N7 | N5 | N3 |
| BEOL rule | | N3 | N3 | N3 | N3 | N3 | N16 | N10 | N7 | N5 | N3 | N3 | N3 | N3 | N3 | N3 |
| M1 rule | | 64 | 47 | 40 | 28 | 23 | 64 | 47 | 40 | 28 | 23 | 64 | 47 | 40 | 28 | 23 |
| Poly cut rule | | 15 | 15 | 15 | 15 | 15 | 48 | 37 | 28 | 20 | 20 | 15 | 15 | 15 | 15 | 15 |
| Gate length | | 28 | 20 | 16 | 14 | 11 | 27 | 19 | 15 | 13 | 10 | 27 | 19 | 15 | 13 | 10 |
| (nm) | | | | | | | | | | | | | | | | |
| Gate pitch | | 52 | 44 | 40 | 38 | 34 | 52 | 44 | 40 | 38 | 34 | 52 | 44 | 40 | 38 | 34 |
| (nm) | | | | | | | | | | | | | | | | |
| Fin | NP | 70 | 52 | 45 | 38 | 37 | 78 | 67 | 58 | 50 | 45 | 75 | 52 | 45 | 45 | 45 |
| pitch | NN | 70 | 52 | 45 | 38 | 37 | 78 | 67 | 58 | 50 | 45 | 75 | 52 | 45 | 45 | 45 |
| (nm) | PP | 48 | 33 | 31 | 28 | 26 | 35 | 35 | 35 | 35 | 35 | 35 | 35 | 35 | 35 | 35 |

| | | | | | | | | | | | | | | | |
|---|---|---|---|---|---|---|---|---|---|---|---|---|---|---|---|
| Cell | 2.7 | 1.7 | 1.3 | 1.1 | 0.9 | 3.3 | 2.2 | 1.7 | 1.4 | 1.2 | 2.7 | 1.7 | 1.5 | 1.4 | 1.2 |
| area ×10⁻² | | | | | | | | | | | | | | | |
| (um²) | | | | | | | | | | | | | | | |
| Cell area | 105 | 166 | 271 | 432 | 1005 | 130 | 216 | 347 | 562 | 1284 | 106 | 173 | 302 | 514 | 1284 |
| (λ²) | | | | | | | | | | | | | | | |
| Cell | 63% | 60% | 52% | 50% | 52% | 55% | 48% | 40% | 35% | 39% | 63% | 58% | 47% | 37% | 39% |
| scaling % | | | | | | | | | | | | | | | |

As shown in Table 1, due to vertical fin shape with better DIBL, gate length and gate pitch of the FinFET 800 (OpCMOS technology) and the NMOS transistor 700 can reduce 35%-11% (NuCMOS technology), in comparison with a conventional 6T SRAM structure. The NN pitch (the distance between two adjacent NMOS transistors) can be scale down 21% due to their self-aligned source/drain regions with landing pads. In addition, the SRAM structure applying the NMOS transistor 700 (NuCMOS technology) may have 36˜22% cell area reduction compared to the SRAM structure applying the FinFET 800 (OpCMOS technology), because the FinFET 800 has diamond-shaped source/drain regions that is greater than the rectangular-shaped source/drain regions of the NMOS transistors 700.

Although, there is no clear area reduction in the SRAM structure applying “NuCMOS+UGI” technology, but the SRAM structure could be more electrical flexible, like power, and/or heat dissipation, due to the application of UGI.

In Table 2, as shown in “NuCMOS+poly cut” Column, the poly cut rule of the FinFETs 1100 (Embodiment 6) used to formed the SRAM structure for N16 (16 nm) to N3 (3 nm) technology node can be reduced to respectively at 15 nm. Furthermore, the NP pitch (the distance between adjacent PMOS transistor and NMOS transistor) and the NN pitch (the distance between two ones of NMOS transistors) can be scale to 70 nm-37 nm for N16 to N3 technology node. In addition, the SRAM structure applying the “NuCMOS+poly cut” technology may have additional cell area reduction compared to the SRAM structure applying the “NuCMOS” technology in Table 1.

In Table 2 again, due to ultra-thin vertical fin shape (˜2 nm) of the VTBFET 1000 (“4CFET in NuCMOS” Column) used to formed the SRAM structure, the gate length for N16 to N3 technology node can be reduced respectively at 27 nm and 10 nm. The NP pitch and the NN pitch can be scaled between 78 nm to 45 nm (for different technology nodes) due to the 10 nm gate length. In addition, the SRAM structure applying “4CFET in NuCMOS” technology may have 55%˜39% cell area reduction compared to the conventional SRAM structure.

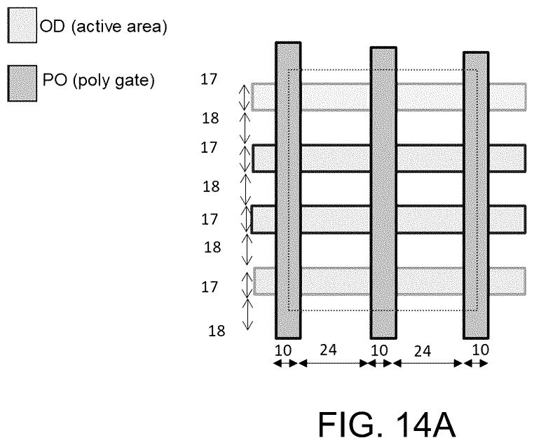

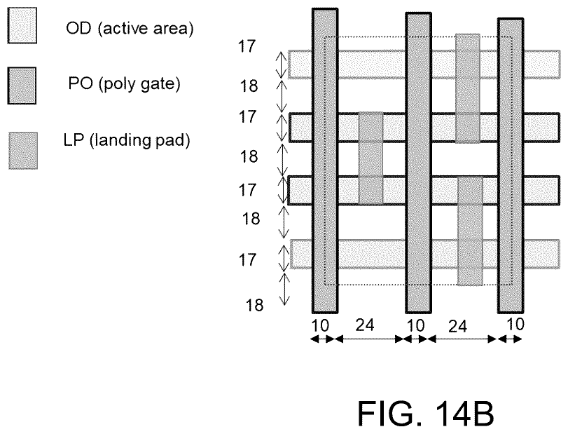

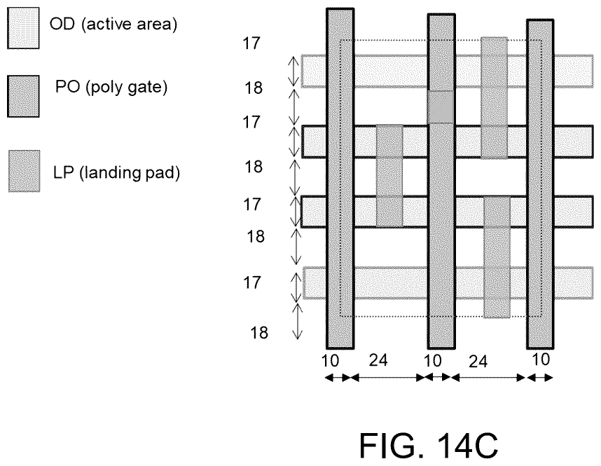

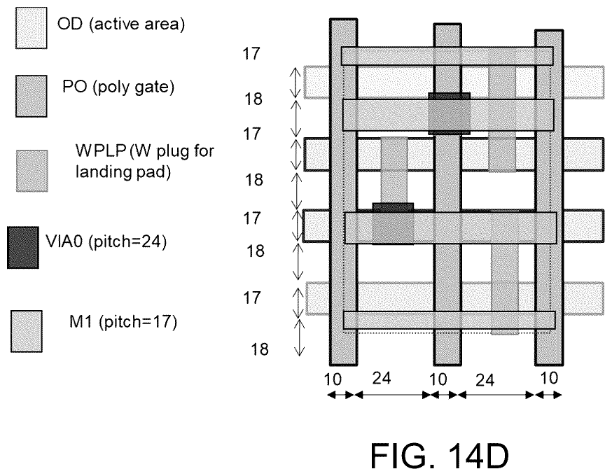

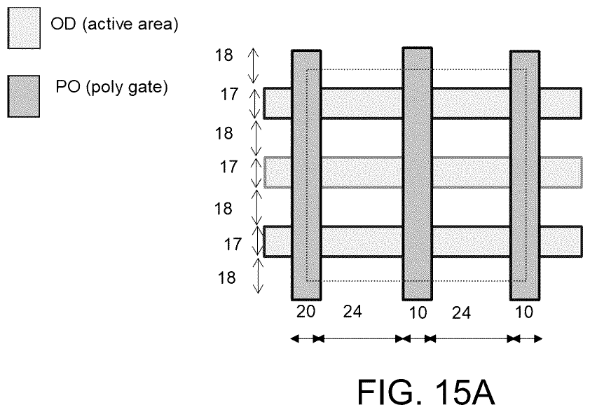

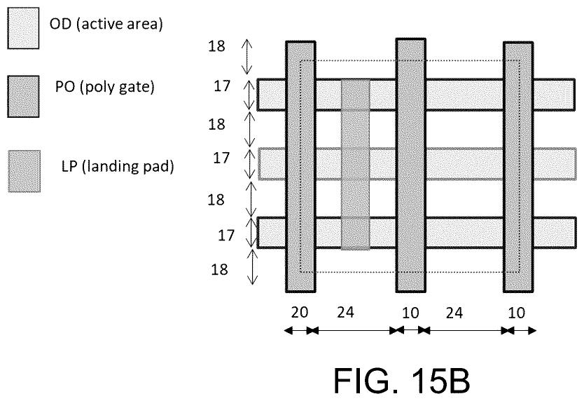

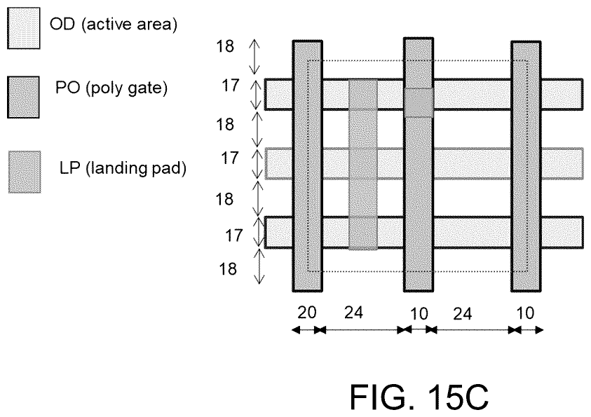

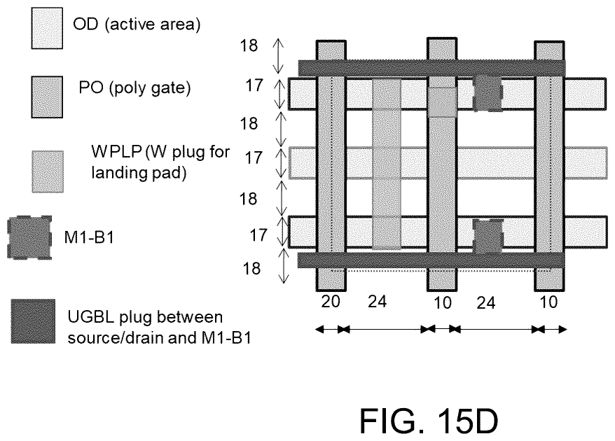

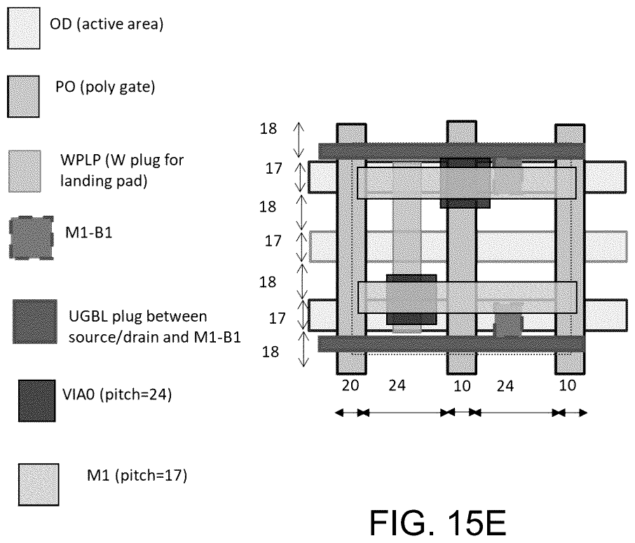

It is noticed that, the present disclosure can be applied to form other semiconductor cell structure, such as logic standard cells. For example, FIGS. 14A to 14D are cross-sectional views illustrating the layout structures for forming a new inverter cell structure applying “4CFET in NuCMOS” technology; and FIGS. 15A to 15E are cross-sectional views illustrating the layout structures for forming another new inverter cell structure applying “4CFET in NuCMOS+UGI” technology. Table 3 shows the cell areas of several new inverter cell structures (embodiments 8˜10) based on “4CFET in NuCMOS” technology.

TABLE 3

| | Conventional inverter cells | | | | | 4CFETs in NuCMOS | | | |
|---|---|---|---|---|---|---|---|---|---|
| Transistor | N16 | N10 | N7 | N5 | N3 | embodiment | embodiment | Embodiment | embodiment |
| node | | | | | | 8 | 9 | 10 | 11 |
| BEOL rule | N16 | N10 | N7 | N5 | N3 | N5 (from tech insights | | N3 (×0.6 from tech | |
| | | | | | | report) | | insights report) | |
| F(λ) | 16 | 10 | 7 | 5 | 3 | 5 | 5 | 3 | 3 |
| Cell height | 576 | 420 | 264 | 217 | 182 | 5*22 | 3*35 | 4*22 | 3*35 |
| (nm) | (12*48) | (10*) | (8*33) | (7*31) | (7*26) | (110) | (105) | (88) | (105) |
| CPP (nm) | 90 | 66 | 57 | 51 | 45 | 42 | 41 | 42 | 41 |
| INVERTER | 0.104 | 0.055 | 0.03 | 0.022 | 0.0164 | 0.00924 | 0.000861 | 0.00739 | 0.00861 |
| Cell area | | | | | | | | | |
| μm² (F²) | (405) | (554) | (614) | (885) | (1820) | (370) | (344) | (821) | (957) |

By applying the “4CFET in NuCMOS” technology of the present disclosure, the cell area of the new inverter cell structures (embodiments 8-11 at different technology node and CPP) can be significantly reduced in comparison with the conventional inverter cell structure. For N5 technology node, the cell area of the new inverter cell structures (embodiments 8 and 9) can be reduced 44% to 47% of a conventional inverter cell structure; and for N3 technology node, the cell area of the new inverter cell structures (embodiments 10 and 11) can be reduced 55% to 47% of a conventional inverter cell structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor cell structure, comprising:
a semiconductor substrate with an original semiconductor surface, wherein the semiconductor substrate comprises a first set active regions and a second set of active regions;
a shallow trench isolation (STI) region surrounding the first set and the second set active regions;
a set of PMOS transistors disposed in the first set active regions, respectively; wherein each PMOS transistor comprises a source region, a drain region, a gate structure, a PMOS region body and a channel region within the PMOS region body;
a set of NMOS transistors disposed in the second set of active regions, respectively; wherein each MMOS transistor comprises a source region, a drain region, a gate structure, a NMOS region body and a channel region within the NMOS region body;
a VDD contacting line electrically coupled to the set of PMOS transistors; and
a VSS contacting line electrically coupled to the set of NMOS transistors;
wherein a bottom surface of the source region of each PMOS transistor are isolated from the semiconductor substrate by a first plurality of localized insulator regions, a bottom surface of the drain region of each PMOS transistor are isolated from the semiconductor substrate by a second plurality of localized insulator regions, and the first and the second plurality of localized insulator regions are disposed below original semiconductor surface;
a bottom surface of the source region of each NMOS transistor are isolated from the semiconductor substrate by a third plurality of localized insulator regions, a bottom surface of the drain region of each NMOS transistor are isolated from the semiconductor substrate by a fourth plurality of localized insulator regions, and the third and the fourth plurality of localized insulator regions are disposed below original semiconductor surface.

2. The semiconductor cell structure according to claim 1, wherein either each PMOS region body or each NMOS region body is fully isolated from the semiconductor substrate by a localized isolation.

3. The semiconductor cell structure according to claim 1, wherein a top surface of the STI region is higher than the original semiconductor surface, and the STI region surrounds the first, the second, the third and/or the fourth plurality of localized insulator regions.

4. The semiconductor cell structure according to claim 3, wherein each localized insulator region of the first, the second, the third and/or the fourth plurality of localized insulator regions includes a L shape insulator within a concave under the original semiconductor surface.

5. The semiconductor cell structure according to claim 4, wherein the source region of a first NMOS transistor is electrically contacting to the channel region of the first NMOS transistor, the source region of the first NMOS transistor is within the concave and includes a epitaxial LDD region laterally extending from the channel region of the first NMOS transistor and a epitaxial heavily doped region laterally extending from the epitaxial LDD region.

6. The semiconductor cell structure according to claim 5, wherein a metal region is disposed within the STI region and the gate structure of the first NMOS transistor, and the metal region contacts a top surface and a most lateral sidewall of the source region of the first NMOS transistor.

7. The semiconductor cell structure according to claim 1, wherein the VDD contacting line or the VSS contacting line is disposed under the original semiconductor surface.

8. The semiconductor cell structure according to claim 7, wherein the VDD contacting line is electrically connected to a first PMOS transistor of the set of PMOS transistors through a contacting plug disposed in one of the first set active regions, and a sidewall of the contacting plug directly contacts to a sidewall of the VDD contacting line; or the VSS contacting line is electrically connected to a first NMOS transistor of the set of NMOS transistors through a contacting plug disposed in one of the second set active regions, and a sidewall of the contacting plug directly contacts to a sidewall of the VSS contacting line.

9. The semiconductor cell structure according to claim 1, further comprising a thermal dissipation layer disposed within the STI region and under the original semiconductor surface, wherein a thermal conductivity of the thermal dissipation layer is higher than that of Si.

10. The semiconductor cell structure according to claim 9, wherein the thermal dissipation layer surrounds the first set active regions and/or the second set active regions.

11. The semiconductor cell structure according to claim 10, wherein the thermal dissipation layer extends from a position close to the first set active regions or the second set active regions to another position close to an edge of the semiconductor substrate.

12. The semiconductor cell structure according to claim 1, wherein a first PMOS transistor of the set of PMOS transistors a first NMOS transistor of the set of NMOS transistors comprises a convex semiconductor structure with at least a trench therein, the convex semiconductor structure comprises a set of thin semiconductor bodies separate from each other, and there is no STI region between any two adjacent thin semiconductor bodies.

13. The semiconductor cell structure according to claim 1, wherein a gate electrode distance between two of the set of NMOS transistors is determined by a width of an inserting dielectric layer.

14. The semiconductor cell structure according to claim 1, wherein the semiconductor cell structure is a SRAM cell, and the SRAM cell further comprises:
a word line electrically coupled to the set of NMOS transistors; and
a bit line and a complementary bit line electrically coupled to the set of NMOS transistors;
wherein when a technology node λ is 16 nm, an cell area of the SRAM cell is between 105˜216λ²; or when the technology node λ is 10 nm, the cell area of the SRAM cell is between 166˜299λ²; or when the technology node λ is 7 nm, the cell area of the SRAM cell is between 271˜451λ²; or when the technology node λ is 5 nm, the cell area of the SRAM cell is between 432˜657λ²; or when the technology node λ is 3 nm, the cell area of the SRAM cell is between 1005˜1588λ².

15. A semiconductor cell structure, comprising:
a semiconductor substrate with an original semiconductor surface, wherein the semiconductor substrate comprises a set of active regions;
a shallow trench isolation (STI) region surrounding the set of active regions;
a set of transistors disposed in the set active regions; wherein each transistor comprises a first epitaxial region, a second epitaxial region, and a gate structure between the first epitaxial region and the second epitaxial region; and
a VDD contacting line and/or a VSS contacting line electrically coupled to the set of transistors;
wherein the set of transistors includes a first transistor and a second transistor adjacent to each other, the first epitaxial region of the first transistor extends along a first direction, and the first epitaxial region of the second transistor extends along the first direction;
wherein the first epitaxial region of the first transistor has a first edge surface, the first epitaxial region of the second transistor has a second edge surface facing the first edge surface, and first edge surface is parallel or substantially parallel to the second edge surface.

16. The semiconductor cell structure according to claim 15, wherein both the first edge surface and the second edge surface are vertical or substantially vertical to the original semiconductor surface.

17. The semiconductor cell structure according to claim 15, wherein a top surface of the STI region is higher than the original semiconductor surface, and surrounds three sides of the first epitaxial region of the first transistor and surrounds three sides of the first epitaxial region of the second transistor.
